(19) United States
(12) Patent Application Publication
(10) Pub. No.: US 2026/0007037 A1
(43) Pub. Date: Jan. 1, 2026

(54) DISPLAY DEVICE, METHOD OF MANUFACTURING DISPLAY DEVICE, AND ELECTRONIC DEVICE

(71) Applicant: Samsung Display Co., Ltd., Yongin-si (KR)

(72) Inventors: Dong Gyun KIM, Yongin-si (KR); Da Sol JEONG, Yongin-si (KR); Seung Hwan CHO, Yongin-si (KR)

(21) Appl. No.: 19/196,490

(22) Filed: May 1, 2025

(30) Foreign Application Priority Data
Jul. 1, 2024 (KR) 10-2024-0086376

(51) Int. Cl. H10K 59/80; H10K 59/12; H10K 59/123

(52) U.S. Cl. CPC H10K 59/80518; H10K 59/1201; H10K 59/123; H10K 59/80515

(57) ABSTRACT

A display device includes: a reflective electrode layer on a substrate; an insulating layer at least partially covering the reflective electrode layer; a first electrode electrically connected to the reflective electrode layer; an emission structure electrically connected to the first electrode; and a second electrode electrically connected to the emission structure. The reflective electrode layer includes a first reflective electrode layer and a second reflective electrode layer. The first electrode includes a (1-1)-th electrode electrically connected to the first reflective electrode layer, and a (1-2)-th electrode electrically connected to the second reflective electrode layer. At least a portion of the insulating layer is located between the (1-2)-th electrode and the second reflective electrode layer. An uppermost conductive layer of the first reflective electrode layer has a first thickness, and an uppermost conductive layer of the second reflective electrode layer has a second thickness equal to the first thickness.

### CROSS-REFERENCE TO RELATED APPLICATION

The present application claims priority to and the benefit of Korean Patent Application No. 10-2024-0086376, filed on Jul. 1, 2024, in the Korean Intellectual Property Office, the entire disclosure of which is incorporated by reference herein.

### BACKGROUND

### 1. Field

Aspects of embodiments of the present disclosure relate to a display device, a method of manufacturing the display device, and an electronic device comprising the display device.

### 2. Description of the Related Art

As interest in an information display is recently increased, research and development on a display device is continuously being conducted.

An organic light emitting diode (OLED) is an active light emitting display element that has a wide viewing angle and excellent contrast, as well as being able to be driven at a low voltage, being lightweight and thin, and having fast response speeds.

An electrical signal for the OLED to emit light may be supplied through a plurality of conductive lines. The plurality of conductive lines may have an intended electrical characteristic (e.g., a resistance), and when the electrical characteristic of the conductive lines is distorted, a risk that a light emitting element may be damaged may occur such that reliability of emission thereby may be reduced.

A display device may include a plurality of layers. The plurality of layers may be patterned based on etching processes. The etching processes may use a mask, and in order to reduce a process cost, a mask requirement may be reduced.

The above information disclosed in this Background section is for enhancement of understanding of the background of the present disclosure, and therefore, it may contain information that does not constitute prior art.

### SUMMARY

Embodiments of the present disclosure may be directed to a display device, a method of manufacturing the display device, and an electronic device comprising the display device, in which a reliability of an electrical signal provided to the display device may be improved.

Embodiments of the present disclosure may be directed to a display device, a method of manufacturing the display device, and an electronic device comprising the display device, in which a risk in a manufacturing process may be reduced and a process may be simplified.

Embodiments of the present disclosure may be directed to a display device having excellent display quality, a method of manufacturing the display device, and an electronic device comprising the display device.

According to one or more embodiments of the present disclosure, a display device includes: a reflective electrode layer on a substrate, and including an uppermost conductive layer; an insulating layer on the substrate, and at least partially covering a portion of the reflective electrode layer; a first electrode electrically connected to the reflective electrode layer; an emission structure electrically connected to the first electrode; and a second electrode electrically connected to the emission structure. The reflective electrode layer includes a first reflective electrode layer in a first sub-pixel area, and a second reflective electrode layer in a second sub-pixel area. The first electrode includes a (1-1)-th electrode in the first sub-pixel area and electrically connected to the first reflective electrode layer, and a (1-2)-th electrode in the second sub-pixel area and electrically connected to the second reflective electrode layer. At least a portion of the insulating layer is located between the (1-2)-th electrode and the second reflective electrode layer. The uppermost conductive layer of the first reflective electrode layer has a first thickness, the uppermost conductive layer of the second reflective electrode layer has a second thickness, and the first thickness and the second thickness are equal to each other.

In an embodiment, the insulating layer may have a first hole exposing the first reflective electrode layer, and a second hole exposing the second reflective electrode layer. The (1-1)-th electrode may be located in the first hole in the first sub-pixel area, and the second hole may be a via hole penetrating the insulating layer in the second sub-pixel area.

In an embodiment, the (1-1)-th electrode and the (1-2)-th electrode may have a flat upper surface, and the (1-2)-th electrode may be electrically connected to the second reflective electrode layer through a contact member located in the second hole.

In an embodiment, the reflective electrode layer may further include a third reflective electrode layer in a third sub-pixel area, and the first electrode may further include a (1-3)-th electrode electrically connected to the third reflective electrode layer. The insulating layer may form a step between the second reflective electrode layer and the (1-2)-th electrode in the second sub-pixel area, may not form a step between the first reflective electrode layer and the (1-1)-th electrode in the first sub-pixel area, and may not form a step between the third reflective electrode layer and the (1-3)-th electrode in the third sub-pixel area.

In an embodiment, the insulating layer may have a first step thickness between the second reflective electrode layer and the (1-2)-th electrode, and the first step thickness may be 80 nm to 140 nm.

In an embodiment, the reflective electrode layer may include a lower reflective electrode layer, an intermediate reflective electrode layer on the lower reflective electrode layer, and an upper reflective electrode layer on the intermediate reflective electrode layer. The uppermost conductive layer may be the upper reflective electrode layer. The lower reflective electrode layer may have a thickness of 8 nm to 12 nm and may include titanium (Ti), the intermediate reflective electrode layer May have a thickness of 75 nm to 85 nm and may include aluminum (Al), and the upper reflective electrode layer may have a thickness of 2 nm to 4 nm and may include titanium nitride (TiN).

In an embodiment, the reflective electrode layer may include a lower reflective electrode layer, an intermediate reflective electrode layer on the lower reflective electrode layer, and an upper reflective electrode layer on the intermediate reflective electrode layer. The uppermost conductive layer may be the upper reflective electrode layer. The lower reflective electrode layer may have a thickness of 2 nm to 15 nm and may have a Ti/TiN/Ti structure, the intermediate reflective electrode layer may have a thickness of 75 nm to 85 nm and may include aluminum (Al), and the upper reflective electrode layer may have a thickness of 2 nm to 30 nm and may have a TiN/ITO structure or a TiN structure.

In an embodiment, the insulating layer may include a first insulating layer, and a second insulating layer on the first insulating layer, and the first and second insulating layers may include an inorganic material.

In an embodiment, the first insulating layer may include silicon oxide (SiOx) when the uppermost conductive layer include ITO, and the first insulating layer may include silicon nitride (SiNx) when the uppermost conductive layer includes TiN.

In an embodiment, the display device may further include: a pixel defining layer on the insulating layer between the first and second sub-pixel areas, and exposing at least a portion of the first electrode; and a trench penetrating the pixel defining layer and the insulating layer. The trench may have a depth of 200 nm to 700 nm and a width of 100 nm to 200 nm, or may have a depth of 200 nm to 1200 nm and a width of 50 nm to 300 nm.

In an embodiment, the display device may further include: a pixel defining layer on the insulating layer between the first and second sub-pixel areas, and exposing at least a portion of the first electrode; and a protruding separator on the pixel defining layer, and including a first protruding separator, and a second protruding separator on the first protruding separator. The second protruding separator may form a tip structure relative to the first protruding separator.

In an embodiment, the reflective electrode layer may further include a third reflective electrode layer in a third sub-pixel area, and the first electrode may further include a (1-3)-th electrode electrically connected to the third reflective electrode layer. The insulating layer may form a step between the second reflective electrode layer and the (1-2)-th electrode in the second sub-pixel area, may not form a step between the first reflective electrode layer and the (1-1)-th electrode in the first sub-pixel area, and may form a step between the third reflective electrode layer and the (1-3)-th electrode in the third sub-pixel area.

In an embodiment, the insulating layer may have a first step thickness between the second reflective electrode layer and the (1-2)-th electrode, and may have a second step thickness between the third reflective electrode layer and the (1-3)-th electrode. The first step thickness and the second step thickness may be equal to each other, and may be 35 nm to 55 nm.

In an embodiment, the reflective electrode layer may further include a third reflective electrode layer in a third sub-pixel area, and the first electrode may further include a (1-3)-th electrode electrically connected to the third reflective electrode layer. The insulating layer may form a step between the second reflective electrode layer and the (1-2)-th electrode in the second sub-pixel area, may not form a step between the first reflective electrode layer and the (1-1)-th electrode in the first sub-pixel area, and may not form a step between the third reflective electrode layer and the (1-3)-th electrode in the third sub-pixel area. The insulating layer may include a first insulating layer, and a second insulating layer on the first insulating layer. The first insulating layer may not cover the first reflective electrode layer and the third reflective electrode layer, and the second insulating layer may cover an upper surface and a side surface of each of the first reflective electrode layer and the third reflective electrode layer.

In an embodiment, the reflective electrode layer may further include a third reflective electrode layer in a third sub-pixel area, and the first electrode may further include a (1-3)-th electrode electrically connected to the third reflective electrode layer. The insulating layer may not form a step between the first reflective electrode layer and the (1-1)-th electrode in the first sub-pixel area, may form a step between the second reflective electrode layer and the (1-2)-th electrode in the second sub-pixel area, and may form a step between the third reflective electrode layer and the (1-3)-th electrode in the third sub-pixel area. The insulating layer may include a first insulating layer, and a second insulating layer on the first insulating layer. The first insulating layer may not cover the first reflective electrode layer, and the second insulating layer may cover an upper surface and a side surface of the first reflective electrode layer.

In an embodiment, the reflective electrode layer may further include a third reflective electrode layer in a third sub-pixel area, and the first electrode may further include a (1-3)-th electrode electrically connected to the third reflective electrode layer. The insulating layer may form a step between the first reflective electrode layer and the (1-1)-th electrode in the first sub-pixel area, may form a step between the second reflective electrode layer and the (1-2)-th electrode in the second sub-pixel area, and may form a step between the third reflective electrode layer and the (1-3)-th electrode in the third sub-pixel area.

In an embodiment, the insulating layer may have a first step thickness between the first reflective electrode layer and the (1-1)-th electrode, a second step thickness between the second reflective electrode layer and the (1-2)-th electrode, and a third step thickness between the third reflective electrode layer and the (1-3)-th electrode. The first step thickness may be 125 nm to 165 nm, the second step thickness may be 320 nm to 380 nm, and the third step thickness may be 125 nm to 165 nm.

In an embodiment, the display device may further include: a pixel-circuit layer including the substrate, a transistor on the substrate, and conductive layers electrically connected to the transistor. The substrate may be a silicon substrate, and the conductive layers may be electrically connected to the reflective electrode layer.

According to one or more embodiments of the present disclosure, a method of manufacturing a display device includes: patterning a reflective electrode layer on a substrate; patterning an insulating layer exposing the reflective electrode layer; patterning a first electrode electrically connected to the reflective electrode layer; forming an emission structure electrically connected to the first electrode; and forming a second electrode electrically connected to the emission structure. The patterning of the reflective electrode layer includes patterning a first reflective electrode layer in a first sub-pixel area, and patterning a second reflective electrode layer in a second sub-pixel area. The patterning of the first electrode includes patterning a (1-1)-th electrode electrically connected to the first reflective electrode layer, and patterning a (1-2)-th electrode electrically connected to the second reflective electrode layer. The patterning of the insulating layer includes forming a first hole exposing the first reflective electrode layer, and forming a second hole exposing the second reflective electrode layer. The insulating layer does not form a step between the first reflective electrode layer and the (1-1)-th electrode, and forms a step between the second reflective electrode layer and the (1-2)-th electrode. The first hole and the second hole are formed in the same process as each other.

In an embodiment, the patterning of the insulating layer may include: forming an area where the (1-1)-th electrode is disposed by exposing the first reflective electrode layer through the first hole; and forming an area where a contact member electrically connecting the (1-2)-th electrode and the second reflective electrode layer to each other is disposed by exposing the second reflective electrode layer through the second hole.

In an embodiment, the patterning of the (1-1)-th electrode may include directly disposing the (1-1)-th electrode on the first reflective electrode layer in the first hole, and the patterning of the (1-2)-th electrode may include directly disposing the (1-2)-th electrode on the insulating layer without disposing the (1-2)-th electrode in the second hole.

In an embodiment, the patterning of the reflective electrode layer may further include patterning a third reflective electrode layer in a third sub-pixel area, and the patterning of the first electrode may further include patterning a (1-3)-th electrode electrically connected to the third reflective electrode layer. The insulating layer may not form a step between the first reflective electrode layer and the (1-1)-th electrode in the first sub-pixel area, may form a step between the second reflective electrode layer and the (1-2)-th electrode in the second sub-pixel area, and may not form a step between the third reflective electrode layer and the (1-3)-th electrode in the third sub-pixel area.

In an embodiment, the patterning of the reflective electrode layer may further include patterning a third reflective electrode layer in a third sub-pixel area, and the patterning of the first electrode may further include patterning a (1-3)-th electrode electrically connected to the third reflective electrode layer. The insulating layer may not form a step between the first reflective electrode layer and the (1-1)-th electrode in the first sub-pixel area, may form a step between the second reflective electrode layer and the (1-2)-th electrode in the second sub-pixel area, and may form a step between the third reflective electrode layer and the (1-3)-th electrode in the third sub-pixel area.

According to one or more embodiments of the present disclosure, an electronic device may comprise: a processor configured to provide input image data; a display device configured to display an image based on the input image data; and a power supply configured to supply power to the display device, The display device includes: a reflective electrode layer on a substrate, and including an uppermost conductive layer; an insulating layer on the substrate, and at least partially covering a portion of the reflective electrode layer; a first electrode electrically connected to the reflective electrode layer; an emission structure electrically connected to the first electrode; and a second electrode electrically connected to the emission structure. The reflective electrode layer includes a first reflective electrode layer in a first sub-pixel area, and a second reflective electrode layer in a second sub-pixel area. The first electrode includes a (1-1)-th electrode in the first sub-pixel area and electrically connected to the first reflective electrode layer, and a (1-2)-th electrode in the second sub-pixel area and electrically connected to the second reflective electrode layer. At least a portion of the insulating layer is located between the (1-2)-th electrode and the second reflective electrode layer. The uppermost conductive layer of the first reflective electrode layer has a first thickness, the uppermost conductive layer of the second reflective electrode layer has a second thickness, and the first thickness and the second thickness are equal to each other.

According to some embodiments of the present disclosure, a display device, a method of manufacturing the display device, and an electronic device comprising the display device may be provided, in which a reliability of an electrical signal provided to the display device may be improved.

According to some embodiments of the present disclosure, a display device, a method of manufacturing the display device, and an electronic device comprising the display device may be provided, in which a risk in a manufacturing process may be reduced and a process may be simplified.

According to some embodiments of the present disclosure, a display device having excellent display quality, a method of manufacturing the display device and an electronic device comprising the display device may be provided.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1 is a schematic plan view illustrating a display device according to an embodiment;

FIG. 2 is a schematic exploded perspective view illustrating a display device according to an embodiment;

FIG. 3 is a schematic plan view illustrating a pixel according to an embodiment;

FIG. 4 is a schematic plan view illustrating a pixel according to another embodiment;

FIG. 5 is a schematic plan view illustrating a pixel according to another embodiment;

FIG. 6 is a schematic cross-sectional view illustrating a pixel-circuit layer according to an embodiment;

FIG. 7 is a schematic cross-sectional view illustrating a display device according to a first embodiment;

FIG. 8 is a schematic cross-sectional view illustrating a thickness relationship between reflective electrode layers according to an embodiment;

FIG. 9 is a schematic cross-sectional view illustrating an emission structure according to an embodiment;

FIG. 10 is a schematic cross-sectional view illustrating an emission structure according to an embodiment;

FIG. 11 is a schematic cross-sectional view illustrating a display device according to a second embodiment;

FIG. 12 is a schematic cross-sectional view illustrating a display device according to a third embodiment;

FIG. 13 is a schematic cross-sectional view illustrating a display device according to a fourth embodiment;

FIG. 14 is a schematic cross-sectional view illustrating a display device according to a fifth embodiment;

FIG. 15 is a schematic cross-sectional view illustrating a display device according to a sixth embodiment;

FIGS. 16-31 are schematic cross-sectional views for processes of a method of manufacturing a display device according to some embodiments;

FIG. 32 is a block diagram illustrating an electronic device according to an embodiment;

FIG. 33 is a perspective view illustrating an application example of the electronic device of FIG. 32; and

FIG. 34 is a diagram illustrating a head mounted display device of FIG. 33 that is worn by a user.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

In the figures, the DR1, the DR2, and the DR3 are not limited to three axes of the rectangular coordinate system, and may be interpreted in a broader sense. For example, the DR1, the DR2, and the DR3 may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

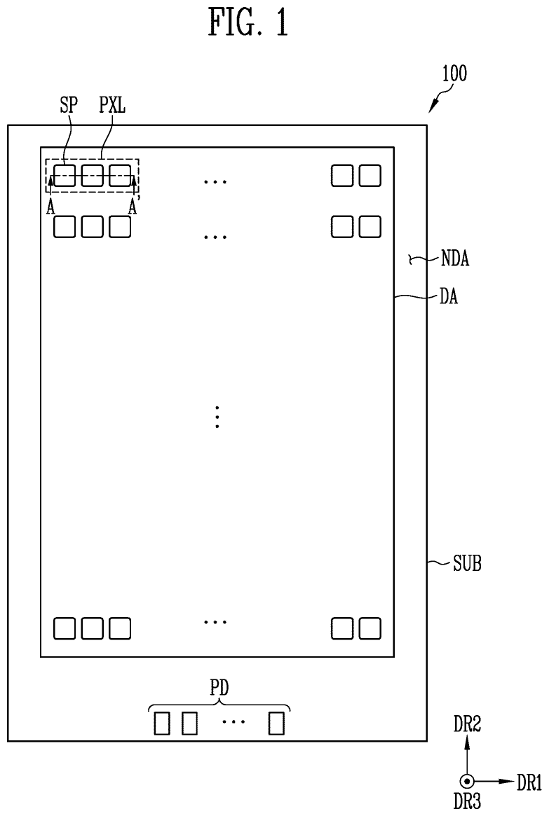

FIG. 1 is a schematic plan view illustrating a display device according to an embodiment.

Referring to FIG. 1, the display device 100 according to an embodiment may emit light.

The display device 100 may include a display area DA and a non-display area NDA. The display device 100 displays an image through the display area DA. The non-display area NDA is disposed around the display area DA. For example, the non-display area NDA may be disposed to surround (e.g., around a periphery of) the display area DA.

The display device 100 may include a substrate SUB, sub-pixels SP, and pads PD.

When the display device 100 is used as a display screen of a head mounted display (HMD) device, a virtual reality (VR) device, a mixed reality (MR) device, an augmented reality (AR) device, or the like, the display device 100 may be positioned to be very close to user's eyes. In this case, the sub-pixels SP of a relatively high integration degree may be desired. In order to increase an integration degree of the sub-pixels SP, the substrate SUB may be provided as a silicon substrate. The sub-pixels SP may be formed on the substrate SUB, which may be the silicon substrate. The display device 100 including a plurality of layers formed on the substrate SUB, which may be the silicon substrate, may be referred to as an OLED on silicon (OLEDoS) display device.

The sub-pixels SP are disposed in the display area DA on the substrate SUB. The sub-pixels SP may be arranged in a matrix form along a first direction DR1 and a second direction DR2 crossing the first direction DR1. However, the present disclosure is not limited thereto. For example, the sub-pixels SP may be arranged in a zigzag shape along the first direction DR1 and the second direction DR2. For example, the sub-pixels SP may be arranged in a diamond shape (e.g., a PENTILE® shape, PENTILE® being a duly registered trademark of Samsung Display Co., Ltd.). The first direction DR1 may be a row direction, and the second direction DR2 may be a column direction.

A plane as used herein may extend in the first direction DR1 and the second direction DR2, and may be defined based on a plane where the substrate SUB is disposed. According to an embodiment, a third direction DR3 may be a thickness direction of the substrate SUB, and the third direction DR3 may be a light emission direction of the display device 100.

The sub-pixels SP may have various suitable shapes in a plan view, and the shape of the sub-pixels SP is not limited to a specific example.

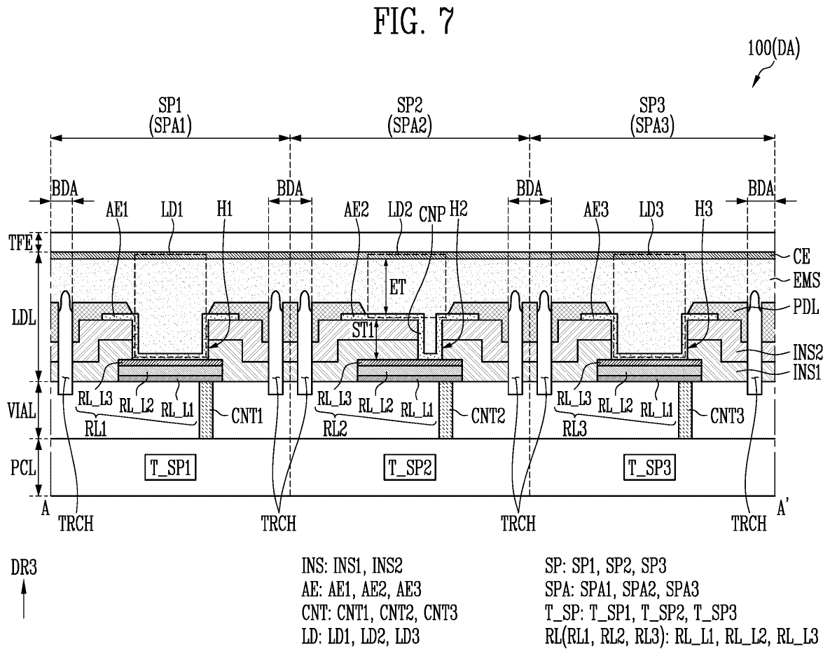

Each of the sub-pixels SP may include at least one light emitting element LD (e.g., refer to FIG. 7) to generate light. Accordingly, each of the sub-pixels SP may generate light of a suitable color, such as red, green, blue, cyan, magenta, or yellow. Two or more sub-pixels SP from among the sub-pixels SP may configure one pixel PXL. For example, as shown in FIG. 1, three sub-pixels SP may configure one pixel PXL.

Hereinafter, for convenience of illustration, the sub-pixels SP may be described in more detail as including a first sub-pixel SP1 for providing light of a first color (e.g., red), a second sub-pixel SP2 for providing light of a second color (e.g., green), and a third sub-pixel SP3 for providing light of a third color (e.g., blue), but the present disclosure is not limited thereto.

According to an embodiment, the first sub-pixel SP1 may be a red pixel, and may provide light of a wavelength band of 600 nm to 750 nm. The second sub-pixel SP2 may be a green pixel, and may provide light of a wavelength band of 480 nm to 560 nm. The third sub-pixel SP3 may be a blue pixel, and may provide light of a wavelength band of 370 nm to 460 nm.

A component for controlling the sub-pixels SP may be disposed in the non-display area NDA on the substrate SUB. For example, lines connected to the sub-pixels SP (e.g., gate lines, data lines, and the like) for driving the sub-pixels SP may be disposed in the non-display area NDA. In addition, a gate driver, a data driver, a voltage generator, a controller, a temperature sensor, and the like for obtaining driving signals supplied to the sub-pixels SP may be integrated into the non-display area NDA of the display device 100. However, the present disclosure is not limited thereto.

The pads PD may be disposed in the non-display area NDA on the substrate SUB. The pads PD may be electrically connected to the sub-pixels SP through some of the lines. For example, the pads PD may be connected to the sub-pixels SP through the data lines.

The pads PD may interface the components in the display area DA and the non-display area NDA with other components of the display device 100. In some embodiments, voltages and signals used for the operation of the components included in the display device 100 may be provided from a driver integrated circuit through the pads PD. For example, the data lines may be electrically connected to the driver integrated circuit through the pads PD. For example, power voltages for driving the sub-pixels SP may be received from the driver integrated circuit through the pads PD. For example, a gate control signal for controlling the gate driver may be transmitted from the driver integrated circuit to the gate driver through the pads PD.

In some embodiments, a circuit board may be electrically connected to the pads PD using a conductive adhesive member, such as an anisotropic conductive film. In this case, the circuit board may be a flexible circuit board (FPCB) or a flexible film having a flexible material. The driver integrated circuit may be mounted on the circuit board to be electrically connected to the pads PD.

In some embodiments, the display area DA may have various suitable shapes. The display area DA may have a closed loop shape including straight and/or curved sides. For example, the display area DA may have various suitable shapes, such as a polygon, a circle, a semicircle, and/or an ellipse.

In some embodiments, the display device 100 may have a flat or substantially flat display surface. In other embodiments, the display device 100 may have a display surface that is at least partially rounded. In some embodiments, the display device 100 may be bendable, foldable, or rollable. In this case, the display device 100 and/or the substrate SUB may include one or more suitable materials having a flexible property.

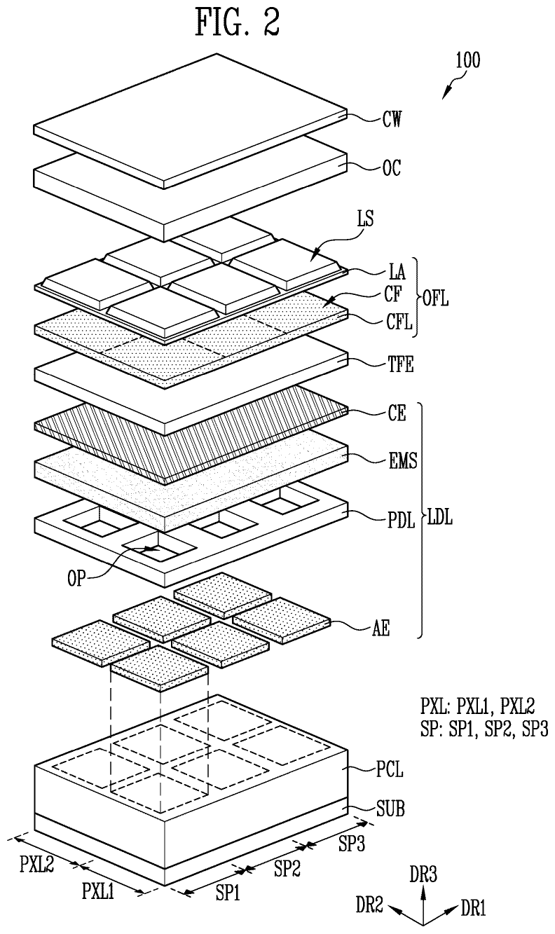

FIG. 2 is a schematic exploded perspective view illustrating a display device according to an embodiment. In FIG. 2, for convenience of illustration, a portion of the display device 100 corresponding to two pixels PXL1 and PXL2 from among the pixels PXL is schematically shown. A portion of the display device 100 corresponding to the other remaining pixels may be configured the same or substantially the same (e.g., similarly).

Referring to FIG. 2, each of the first and second pixels PXL1 and PXL2 may include first to third sub-pixels SP1 to SP3. However, the present disclosure is not limited thereto. For example, each of the first and second pixels PXL1 and PXL2 may include four sub-pixels or two sub-pixels.

In FIG. 2, the first to third sub-pixels SP1 to SP3 have quadrangle shapes when viewed from the third direction DR3 crossing the first and second directions DR1 and DR2 (e.g., in a plan view), and may have sizes that are equal to or substantially equal to each other. However, the present disclosure is not limited thereto. The first to third sub-pixels SP1 to SP3 may be variously modified as needed or desired to have various suitable shapes.

The display device 100 may include a pixel-circuit layer PCL including the substrate SUB. The display device 100 may further include a light-emitting-element layer LDL, an encapsulation layer TFE, an optical functional layer OFL, an overcoat layer OC, and a cover window CW.

In some embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOI) layer, or the like. In other embodiments, the substrate SUB may include a glass substrate. In other embodiments, the substrate SUB may include a polyimide (PI) substrate.

A plurality of other layers forming the pixel-circuit layer PCL are disposed on the substrate SUB. The pixel-circuit layer PCL including the substrate may include insulating layers, and conductive patterns disposed between the insulating layers. The conductive patterns of the pixel-circuit layer PCL may function as at least a portion of the circuit elements, the lines, and the like. The conductive patterns may include various suitable conductive materials, and the present disclosure is not limited to a specific example. The circuit elements may include a pixel circuit for each of the first to third sub-pixels SP1 to SP3. The pixel circuit may include transistors and one or more capacitors.

The light-emitting-element layer LDL may include first electrodes AE, a pixel defining layer PDL, an emission structure EMS, and a second electrode CE.

The first electrodes AE may be disposed on the pixel-circuit layer PCL. The first electrodes AE may be electrically connected to the circuit elements of the pixel-circuit layer PCL.

According to an embodiment, the first electrodes AE may be anode electrodes.

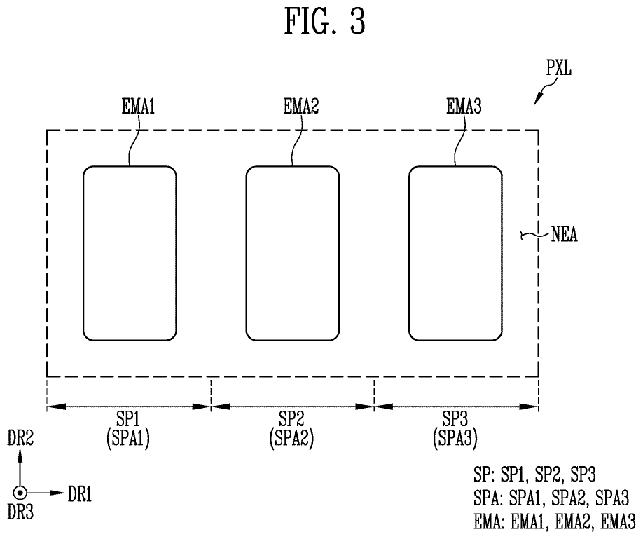

The pixel defining layer PDL is disposed on the first electrodes AE. The pixel defining layer PDL may include openings OP exposing a portion of each of the first electrodes AE. The openings OP of the pixel defining layer PDL may be understood as emission areas EMA (e.g., refer to FIG. 3) corresponding to the first to third sub-pixels SP1 to SP3, respectively. According to an embodiment, the light-emitting element LD may be defined (e.g., formed) within the opening OP of the pixel defining layer PDL in a plan view.

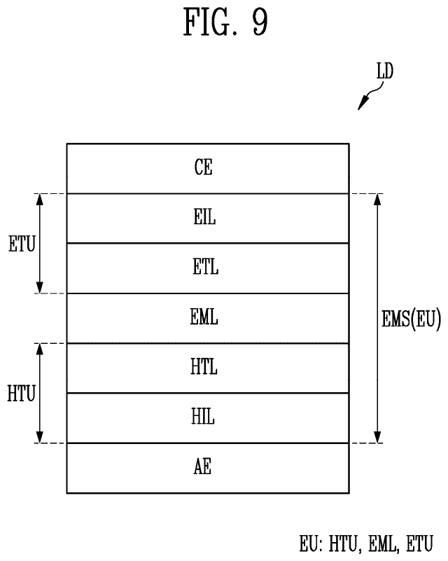

The emission structure EMS may be disposed on the first electrodes AE exposed by the openings OP of the pixel defining layer PDL. The emission structure EMS may include a light emitting layer EML (e.g., refer to FIG. 9) to generate light, an electron transport unit ETU (e.g., an electron transport layer) to transport an electron, a hole transport unit HTU (e.g., a hole transport layer) to transport a hole, and the like.

In some embodiments, the emission structure EMS may fill the openings OP of the pixel defining layer PDL, and may be entirely disposed on the pixel defining layer PDL. In other words, the emission structure EMS may extend across the first to third sub-pixels SP1 to SP3. In this case, at least a portion of layers in the emission structure EMS may be disconnected or bent at boundaries between the first to third sub-pixels SP1 to SP3.

The second electrode CE may be disposed on the emission structure EMS. The second electrode CE may extend across the first to third sub-pixels SP1 to SP3. As described above, the second electrode CE may be provided as a common electrode for the first to third sub-pixels SP1 to SP3.

According to an embodiment, the second electrode CE may be a cathode electrode.

The second electrode CE may be a thin metal layer having a thickness sufficient to transmit light emitted from the emission structure EMS. The second electrode CE may supply a cathode voltage to the emission structure EMS.

As used herein, a thickness may be defined based on the third direction DR3.

According to an embodiment, the second electrode CE may be a thin metal layer having a thickness sufficient to transmit light emitted from the emission structure EMS. The second electrode CE may be formed of a metal material or a transparent conductive material to have a relatively thin thickness. In some embodiments, the second electrode CE may include at least one of various suitable transparent conductive materials including indium tin oxide (ITO), indium zinc oxide (IZO), indium gallium zinc oxide (IGZO), aluminum zinc oxide (AZO), indium tin zinc oxide (ITZO), zinc oxide (ZnO), or tin oxide (SnO2). In other embodiments, the second electrode CE may include at least one of silver (Ag), magnesium (Mg), or a suitable mixture thereof. However, the material of the second electrode CE is not limited thereto.

It may be understood that any one of the first electrodes AE, a portion of the emission structure EMS overlapping with the one first electrode AE, and a portion of the second electrode CE overlapping with the one first electrode AE may configure one light emitting element LD. In other words, each of the light emitting elements LD of the first to third sub-pixels SP1 to SP3 may include one first electrode AE, a portion of the emission structure EMS overlapping with the one first electrode AE, and a portion of the second electrode CE overlapping with the one first electrode AE. In each of the first to third sub-pixels SP1 to SP3, holes injected from the first electrode AE and electrons injected from the second electrode CE may be transported into the light emitting layer EML of the emission structure EMS to form excitons, and when the excitons transits from an excited state to a ground state, light may be generated. A luminance of the light may be determined according to an amount of a current flowing through the light emitting layer EML. According to a configuration of the light emitting layer EML, a wavelength range of the generated light may be determined.

The encapsulation layer TFE is disposed on the second electrode CE. The encapsulation layer TFE may cover the light-emitting-element layer LDL and the pixel-circuit layer PCL. The encapsulation layer TFE may prevent or substantially prevent oxygen, moisture, and/or the like from permeating to the light-emitting-element layer LDL. In some embodiments, the encapsulation layer TFE may include a structure in which one or more inorganic layers and one or more organic layers are alternately stacked. For example, the inorganic layer may include silicon nitride, silicon oxide, silicon oxynitride (SiOxNy), or the like. For example, the organic layer may include an organic insulating material, such as an acrylic resin, an epoxy resin, a phenol resin, a polyamide resin, a polyimide resin, an unsaturated polyester resin, a polyphenylenether resin, a polyphenylenesulfide resin, or benzocyclobutene (BCB) resin. However, the materials of the organic and the inorganic layers of the encapsulation layer TFE are not limited thereto.

The optical functional layer OFL is disposed on the encapsulation layer TFE. The optical functional layer OFL may include a color filter layer CFL and a lens array LA.

The color filter layer CFL may be disposed between the encapsulation layer TFE and the lens array LA. The color filter layer CFL may filter the light emitted from the emission structure EMS, and may selectively output light of a wavelength range or a color corresponding to each sub-pixel. The color filter layer CFL may include color filters CF corresponding to the first to third sub-pixels SP1 to SP3, respectively, and each of the color filters CF may pass light of a wavelength range corresponding to the corresponding sub-pixel. For example, the color filter corresponding to the first sub-pixel SP1 may pass a red color light, the color filter corresponding to the second sub-pixel SP2 may pass a green color light, and the color filter corresponding to the third sub-pixel SP3 may pass a blue color light. According to the light (e.g., the color of light) emitted from the emission structure EMS of each sub-pixel, at least a portion of the color filters CF may be omitted.

The lens array LA may be disposed on the color filter layer CFL. The lens array LA may include lenses LS corresponding to the first to third sub-pixels SP1 to SP3, respectively. Each of the lenses LS may improve a light output efficiency by outputting the light emitted from the emission structure EMS to an intended path. The lens array LA may have a relatively high refractive index. For example, the lens array LA may have a refractive index higher than that of the overcoat layer OC. In some embodiments, the lenses LS may include an organic material. In some embodiments, the lenses LS may include an acrylic material. However, the material of the lenses LS is not limited thereto.

The overcoat layer OC may be disposed on the lens array LA. The overcoat layer OC may cover the optical functional layer OFL, the encapsulation layer TFE, the emission structure EMS, and/or the pixel-circuit layer PCL. The overcoat layer OC may include various materials suitable for protecting the layers thereunder from a foreign substance, such as dust or moisture. For example, the overcoat layer OC May include at least one of an inorganic insulating layer and an organic insulating layer. For example, the overcoat layer OC may include an epoxy, but the present disclosure is not limited thereto. The overcoat layer OC may have a refractive index lower than that of the lens array LA.

The cover window CW may be disposed on the overcoat layer OC. The cover window CW may protect the layers thereunder. The cover window CW may have a refractive index higher than that of the overcoat layer OC. The cover window CW may include glass, but the present disclosure is not limited thereto. For example, the cover window CW may be an encapsulation glass to protect the components disposed thereunder. In other embodiments, the cover window CW may be omitted as needed or desired.

FIG. 3 is a schematic plan view illustrating a pixel according to an embodiment.

Referring to FIG. 3, the pixel PXL may include sub-pixels SP arranged along the first direction DR1. For example, the sub-pixels SP may include a first sub-pixel SP1, a second sub-pixel SP2, and a third sub-pixel SP3 arranged along the first direction DR1. The emission areas EMA may include first to third emission areas EMA1 to EMA3.

The sub-pixels SP may include a sub-pixel area SPA. The sub-pixel area SPA may be an area where one color is provided. The sub-pixel area SPA may overlap with the emission area EMA. According to an embodiment, the sub-pixel area SPA may include a first sub-pixel area SPA1 formed by the first sub-pixel SP1, a second sub-pixel area SPA2 formed by the second sub-pixel SP2, and a third sub-pixel area SPA3 formed by the third sub-pixel SP3.

The first sub-pixel SP1 may include the first emission area EMA1, and a non-emission area NEA around the first emission area EMA1. The second sub-pixel SP2 may include the second emission area EMA2, and a non-emission area NEA around the second emission area EMA2. The third sub-pixel SP3 may include the third emission area EMA3, and a non-emission area NEA around the third emission area EMA3.

The first emission area EMA1 may be an area where light is emitted from a portion of the emission structure EMS corresponding to the first sub-pixel SP1 (e.g., a first emission structure). The second emission area EMA2 may be an area where light is emitted from a portion of the emission structure EMS corresponding to the second sub-pixel SP2 (e.g., a second emission structure). The third emission area EMA3 may be an area where light is emitted from a portion of the emission structure EMS corresponding to the third sub-pixel SP3 (e.g., a third emission structure). As described above with reference to FIG. 2, each emission area may be understood as a corresponding opening OP of the pixel defining layer PDL corresponding to each of the first sub-pixel SP1, the second sub-pixel SP2, and the third sub-pixel SP3.

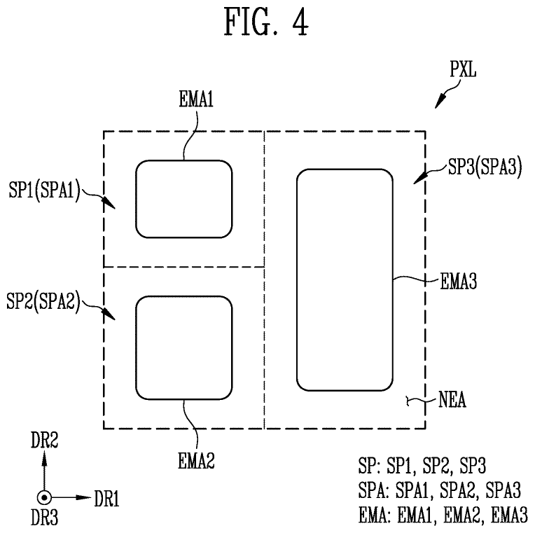

FIG. 4 is a schematic plan view illustrating a pixel according to another embodiment.

Referring to FIG. 4, the first sub-pixel SP1 and the second sub-pixel SP2 may be arranged along the second direction DR2. The third sub-pixel SP3 may be arranged in the first direction DR1 with respect to each of the first and second sub-pixels SP1 and SP2.

The second sub-pixel SP2 may have an area greater than that of the first sub-pixel SP1, and the third sub-pixel SP3 may have an area greater than that of the second sub-pixel SP2. Accordingly, the second emission area EMA2 may have a area greater than that of the first emission area EMA1, and the third emission area EMA3 may have a area greater than that of the second emission area EMA2. However, the present disclosure is not limited thereto. For example, the first and second sub-pixels SP1 and SP2 may have the same or substantially the same area as each other, and the third sub-pixel SP3 may have an area greater than that of each of the first and second sub-pixels SP1 and SP2. As described above, the areas of the first to third sub-pixels SP1 to SP3 may be variously modified as needed or desired.

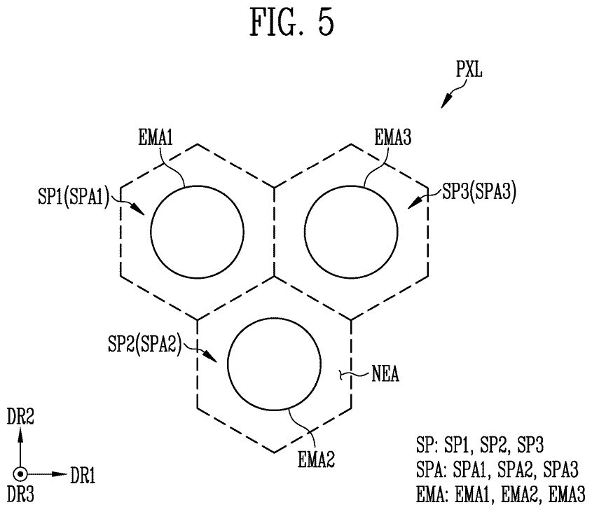

FIG. 5 is a schematic plan view illustrating a pixel according to another embodiment.

Referring to FIG. 5, the first to third sub-pixels SP1 to SP3 may have polygonal shapes when viewed in the third direction DR3 (e.g., in a plan view). For example, the shapes of the first to third sub-pixels SP1 to SP3 may be hexagonal shapes as shown in FIG. 5.

The first to third emission areas EMA1 to EMA3 may have circular shapes when viewed in the third direction DR3 (e.g., in a plan view). However, the present disclosure is not limited thereto. For example, each of the first to third emission areas EMA1 to EMA3 may have a polygonal shape.

The first and third sub-pixels SP1 and SP3 may be arranged along the first direction DR1. The second sub-pixel SP2 may be disposed in a direction (e.g., a diagonal direction) inclined by an acute angle based on the second direction DR2 with respect to the first sub-pixel SP1. In other words, the second sub-pixel SP2 may be disposed in a direction between the first and second directions DR1 and DR2 with respect to the third sub-pixel SP3.

The arrangements of the sub-pixels SP shown in FIGS. 3 to 5 are provided for convenience of illustration, and the present disclosure is not limited thereto. Each pixel PXL may include two or more sub-pixels SP, the sub-pixels SP may be arranged in various suitable forms or methods, the sub-pixels SP may have various suitable shapes, and the emission areas EMA thereof may also have various suitable shapes.

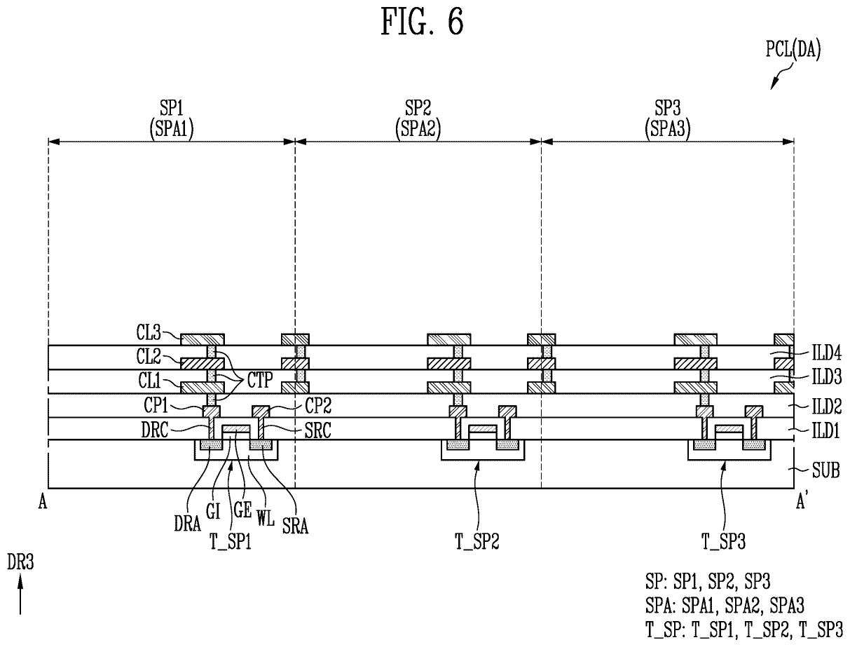

A cross-sectional structure of the display device 100 according to an embodiment will be described in more detail below with reference to FIGS. 6 to 13.

First, referring to FIGS. 6 to 10, a display device 100 according to a first embodiment will be described in more detail.

FIG. 6 is a schematic cross-sectional view illustrating a pixel-circuit layer according to an embodiment. FIG. 7 is a schematic cross-sectional view illustrating a display device according to the first embodiment. FIGS. 6 and 7 are schematic cross-sectional views taken along the line A-A′ of FIG. 1. FIGS. 6 and 7 schematically show a partial cross-sectional structure of the display device 100 in the display area DA.

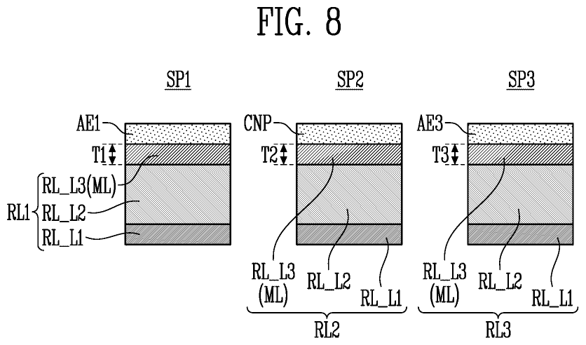

FIG. 8 is a schematic cross-sectional view illustrating a thickness relationship between reflective electrode layers according to an embodiment.

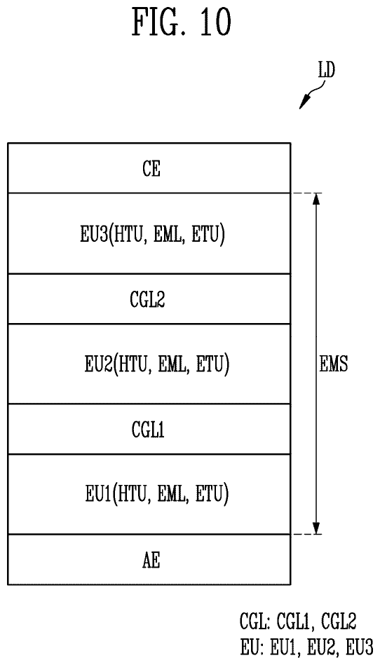

FIG. 9 is a schematic cross-sectional view illustrating an emission structure according to an embodiment. FIG. 10 is a schematic cross-sectional view illustrating an emission structure according to an embodiment.

Referring to FIG. 6, the pixel-circuit layer PCL may include the substrate SUB, and transistors T_SP formed on the substrate SUB. The pixel-circuit layer PCL may include conductive layers including first to third conductive layers CL1 to CL3, and interlayer insulating layers including first to fourth interlayer insulating layers ILD1 to ILD4.

Circuit elements including the transistors T_SP may be patterned on the substrate SUB. The transistors T_SP may drive a light emitting element LD. The transistors T_SP may include a first transistor T_SP1 for driving the first sub-pixel SP1, a second transistor T_SP2 for driving the second sub-pixel SP2, and a third transistor T_SP3 for driving the third sub-pixel SP3.

Each of the transistors T_SP may include a source area SRA, a drain area DRA, and a gate electrode GE.

The source area SRA and the drain area DRA may be disposed in the substrate SUB. A well WL formed through an ion implantation process may be disposed in the substrate SUB, and the source area SRA and the drain area DRA may be disposed to be spaced apart from each other in the well WL. An area between the source area SRA and the drain area DRA in the well WL may be defined as a channel area.

The gate electrode GE may overlap with the channel area between the source area SRA and the drain area DRA, and may be disposed in the pixel-circuit layer PCL. The gate electrode GE may be spaced apart from the well WL or the channel area by an insulating material, such as a gate insulating layer GI. The gate electrode GE may include a conductive material.

The first interlayer insulating layer ILD1 may cover the gate electrode GE and the gate insulating layer GI, and may be disposed on the substrate SUB. The first interlayer insulating layer ILD1 may include an inorganic material, such as silicon oxide (SiOx) and/or silicon nitride (SiNx), and may have a single layer structure or a multiple layered structure.

First and second conductive pattern layers CP1 and CP2 may be disposed on the first interlayer insulating layer ILD1. The first conductive pattern layer CP1 may be electrically connected to the drain area DRA through a drain connection portion DRC passing through (e.g., penetrating) the first interlayer insulating layer ILD1. The second conductive pattern layer CP2 may be electrically connected to the source area SRA through a source connection portion SRC passing through (e.g., penetrating) the first interlayer insulating layer ILD1.

As the gate electrode GE and the first and second conductive pattern layers CP1 and CP2 are electrically connected to other circuit elements and/or lines, a portion of the circuit elements may be formed.

The second interlayer insulating layer ILD2 may cover the first and second conductive pattern layers CP1 and CP2, and may be disposed on the first interlayer insulating layer ILD1. The second interlayer insulating layer ILD2 may include an inorganic material, such as silicon oxide (SiOx) and/or silicon nitride (SiNx), and may have a single layered structure or a multiple layered structure.

The first conductive layer CL1 may be disposed on the second interlayer insulating layer ILD2. A portion of the first conductive layer CL1 may be electrically connected to the first conductive pattern layer CP1 (or, the transistor T_SP) through a contact portion CTP passing through (e.g., penetrating) the second interlayer insulating layer ILD2. Another portion of the first conductive layer CL1 may be disposed between adjacent sub-pixel areas SPA, and may form another portion of the circuit element.

The third interlayer insulating layer ILD3 may cover the first conductive layer CL1, and may be disposed on the second interlayer insulating layer ILD2. The third interlayer insulating layer ILD3 may include an inorganic material, such as silicon oxide (SiOx) and/or silicon nitride (SiNx), and may have a single layer structure or a multiple layered structure.

The second conductive layer CL2 may be disposed on the third interlayer insulating layer ILD3. A portion of the second conductive layer CL2 may be electrically connected to the first conductive layer CL1 through a contact portion CTP passing through (e.g., penetrating) the third interlayer insulating layer ILD3. Another portion of the second conductive layer CL2 may be disposed between adjacent sub-pixel areas SPA, and may form another portion of the circuit element.

The fourth interlayer insulating layer ILD4 may cover the second conductive layer CL2, and may be disposed on the third interlayer insulating layer ILD3. The fourth interlayer insulating layer ILD4 may include an inorganic material, such as silicon oxide (SiOx) and/or silicon nitride (SiNx), and may have a single layer structure or a multiple layered structure.

The third conductive layer CL3 may be disposed on the fourth interlayer insulating layer ILD4. A portion of the third conductive layer CL3 may be electrically connected to the second conductive layer CL2 through a contact portion CTP passing through (e.g., penetrating) the fourth interlayer insulating layer ILD4. Another portion of the third conductive layer CL3 may be disposed between adjacent sub-pixel areas SPA, and may form another portion of the circuit element.

According to an embodiment, each of the first to third conductive layers CL1 to CL3 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), or a suitable alloy of two or more materials selected from them. For example, each of the first to third conductive layers CL1 to CL3 may have a Ti/Al/TiN structure. According to an embodiment, the contact portion CTP may include a conductive material, such as tungsten (W). However, the present disclosure is not limited thereto.

A structure of the pixel-circuit layer PCL is not necessarily limited to that described above, and may be variously modified as needed or desired as would be understood by those having ordinary skill in the art.

Referring to FIG. 7, the display device 100 may include a via layer VIAL, the light-emitting-element layer LDL, and the encapsulation layer TFE disposed on the pixel-circuit layer PCL. For convenience of illustration, FIG. 7 schematically shows the pixel-circuit layer PCL.

The via layer VIAL may be disposed on the pixel-circuit layer PCL. The via layer VIAL may be a planarization layer. The via layer VIAL may include an organic material. However, the present disclosure is not limited thereto.

The light-emitting-element layer LDL may be disposed on the via layer VIAL. The light-emitting-element layer LDL may include a reflective electrode layer RL, an insulating layer INS, the first electrodes AE, the pixel defining layer PDL, a trench TRCH, the emission structure EMS, and the second electrode CE.

The reflective electrode layer RL may be disposed on the via layer VIAL. According to an embodiment, a portion of a lower surface of the reflective electrode layer RL may contact an upper surface of the via layer VIAL.

The reflective electrode layer RL may be formed in each of the first to third sub-pixels SP1 to SP3. For example, the reflective electrode layer RL may include a first reflective electrode layer RL1 disposed in the first sub-pixel area SPA1, a second reflective electrode layer RL2 disposed in the second sub-pixel area SPA2, and a third reflective electrode layer RL3 disposed in the third sub-pixel area SPA3.

The reflective electrode layer RL may include a plurality of layers that are stacked in each of the sub-pixel areas SPA. For example, the reflective electrode layer RL may include a lower reflective electrode layer RL_L1, an intermediate reflective electrode layer RL_L2, and an upper reflective electrode layer RL_L3.

The reflective electrode layer RL of each of the first to third sub-pixels SP1 to SP3 may be patterned in the same process as each other, and may include the same conductive material as each other.

For example, the lower reflective electrode layers RL_L1 of each of the first to third sub-pixels SP1 to SP3 may be patterned in the same process as each other, and may include the same conductive material as each other. The intermediate reflective electrode layers RL_L2 of each of the first to third sub-pixels SP1 to SP3 may be patterned in the same process as each other, and may include the same conductive material as each other. The upper reflective electrode layers RL_L3 of each of the first to third sub-pixels SP1 to SP3 may be patterned in the same process as each other, and may include the same conductive material as each other.

The reflective electrode layer RL may be electrically connected to at least a portion (e.g., the transistor T_SP) of the circuit elements formed in the pixel-circuit layer PCL through a contact portion CNT formed in the via layer VIAL. The contact portion CNT may include a first contact portion CNT1 electrically connecting the first reflective electrode layer RL1 and a first transistor T_SP1 to each other, a second contact portion CNT2 electrically connecting the second reflective electrode layer RL2 and a second transistor T_SP2 to each other, and a third contact portion CNT3 electrically connecting the third reflective electrode layer RL3 and a third transistor T_SP3 to each other.

The reflective electrode layer RL may function as a full mirror that reflects light emitted from the emission structure EMS toward the display surface (e.g., the cover window CW). Light emitted from the light emitting layer EML of the emission structure EMS may be amplified by at least partially reciprocating between the corresponding reflective electrode layer RL and the second electrode CE, and the amplified light may be output through the second electrode CE. As described above, a distance between each reflective electrode layer RL and the second electrode CE may be understood as a resonance distance for the light emitted from the corresponding light emitting layer EML of the emission structure EMS.

According to an embodiment, at least a portion of the reflective electrode layer RL may include one or more metal materials suitable for reflecting light. For example, the metal materials may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), or a suitable alloy of two or more materials selected from them.

The lower reflective electrode layer RL_L1 may include titanium (Ti). For example, the lower reflective electrode layer RL_L1 may have a Ti/TiN/Ti structure. In this case, an adhesion characteristic between the intermediate reflective electrode layer RL_L2 including aluminum (Al) and the lower reflective electrode layer RL_L1 may be improved, a roughness of the intermediate reflective electrode layer RL_L2 may be alleviated, and a risk that a material such as titanium is diffused during a heat treatment process for manufacturing of the lower reflective electrode layer RL_L1 may be reduced. According to an embodiment, the lower reflective electrode layer RL_L1 may have a thickness of 8 nm to 12 nm. As another example, when the lower reflective electrode layer RL_L1 has a Ti/TiN/Ti structure, the lower reflective electrode layer RL_L1 may have a thickness of 2 nm to 15 nm.

The intermediate reflective electrode layer RL_L2 may include aluminum (Al). The intermediate reflective electrode layer RL_L2 may have a thickness of 75 nm to 85 nm.

The upper reflective electrode layer RL_L3 may include titanium nitride (TiN). For example, the upper reflective electrode layer RL_L3 may have a TiN/ITO structure or a TiN structure. According to an embodiment, the upper reflective electrode layer RL_L3 may have a thickness of 2 nm to 4 nm. As another example, when the upper reflective electrode layer RL_L3 has a TiN/ITO structure or a TiN structure, the upper reflective electrode layer RL_L3 may have a thickness of 2 nm to 30 nm.

The insulating layer INS may be disposed on the via layer VIAL, may cover a portion of the reflective electrode layer RL, and may expose another portion of the reflective electrode layer RL.

According to an embodiment, the insulating layer INS may include a plurality of layers. For example, the insulating layer INS may include a first insulating layer INS1, and a second insulating layer INS2 disposed on the first insulating layer INS1.

The insulating layer INS may include an insulating material. For example, the insulating layer INS may include an inorganic material. The inorganic material may include one or more of silicon oxide (SiOx), silicon nitride (SiNx), and/or silicon oxynitride (SiOxNy). For example, the first insulating layer INS1 may include silicon oxide, and the second insulating layer INS2 may include silicon nitride (SiNx). As another example, the first insulating layer INS1 may include silicon nitride (SiNx), and the second insulating layer INS2 may include silicon oxide (SiOx). As another example, the first insulating layer INS1 may include silicon oxide (SiOx), and the second insulating layer INS2 may include silicon oxide (SiOx). As another example, the first insulating layer INS1 may include silicon nitride (SiNx), and the second insulating layer INS2 may include silicon nitride (SiNx). However, the present disclosure is not limited thereto.

According to an embodiment, the first insulating layer INS1 may include an inorganic material corresponding to a material of an uppermost conductive layer ML (e.g., see FIG. 8). For example, when the uppermost conductive layer ML includes a conductive oxide, such as (ITO), the first insulating layer INS1 may include silicon oxide (SiOx). As another example, when the uppermost conductive layer ML includes a conductive nitride, such as TIN, the first insulating layer INS1 may include silicon nitride (SiNx).

The insulating layer INS may form a step under the first electrode AE of a portion of the sub-pixels SP in an area where the light emitting element LD is formed. For example, the insulating layer INS may be a step forming layer for the light emitting element LD (e.g., the second light emitting element LD2) of the second sub-pixel SP2, and may not form a step for the light emitting elements LD (e.g., the first and third light emitting elements LD1 and LD3) of the first and third sub-pixels SP1 and SP3.

For example, the second sub-pixel SP2 may have a resonance distance shorter than those of the first and third sub-pixels SP1 and SP3 due to a step structure formed by the insulating layer INS. The resonance distance adjusted as described above may allow light of a specific wavelength range to be amplified effectively and efficiently, and may allow a light efficiency between the sub-pixels SP to be generally uniformly provided.

According to an embodiment, in the second sub-pixel SP2, the insulating layer INS may form a step having a first step thickness ST1 between a (1-2)-th electrode AE2 and the second reflective electrode layer RL2. According to an embodiment, the first step thickness ST1 may be defined based on the insulating layer INS, and when the insulating layer INS includes the first insulating layer INS1 and the second insulating layer INS2, the first step thickness ST1 may be a sum of a thicknesses of each of the first insulating layer INS1 and the second insulating layer INS2.

According to an embodiment, each of the first step thickness ST1 and a thickness of the emission structure EMS may have a suitable numerical range (e.g., a predetermined numerical range). For example, an emission thickness ET of the emission structure EMS may be 300 nm to 350 nm. According to an embodiment, the emission thickness ET of the emission structure EMS may be about 320 nm. The first step thickness ST1 may be 80 nm to 140 nm. As another example, the first step thickness ST1 may be 110 nm to 130 nm. According to an embodiment, the first step thickness ST1 may be about 120 nm. However, the present disclosure is not necessarily limited thereto.

According to an embodiment, when the emission thickness ET and the first step thickness ST1 satisfy the above-described numerical range, an emission efficiency of the first to third sub-pixels SP1 to SP3 may have generally uniformly excellent efficiency.

The first electrodes AE may be disposed on the pixel-circuit layer PCL (or, the via layer VIAL). The first electrodes AE may cover a portion of the insulating layer INS.

The first electrodes AE may include a (1-1)-th electrode AE1 of the first sub-pixel SP1, a (1-2)-th electrode AE2 of the second sub-pixel SP2, and a (1-3)-th electrode AE3 of the third sub-pixel SP3.

The first electrode AE may be electrically connected to the reflective electrode layer RL. Accordingly, the first electrode AE may be electrically connected to the circuit element of the pixel-circuit layer PCL, and may receive an anode signal (e.g., a voltage).

The first electrode AE may include a transparent conductive material. For example, the first electrode AE may include at least one of various suitable transparent conductive materials, such as indium tin oxide (ITO), indium zinc oxide (IZO), zinc oxide (ZnOx), indium gallium zinc oxide (IGZO), and/or indium tin zinc oxide (ITZO). However, the material of the first electrode AE is not limited thereto. For example, the first electrode AE may include titanium nitride.

According to an embodiment, the first electrode AE may have a thickness of 10 nm to 30 nm.

According to an embodiment, the first electrodes AE may be electrically connected to the reflective electrode layer RL based on a structure different for each of the sub-pixels SP.

When a step is formed by the insulating layer INS under a portion of the light emitting element LD from among the sub-pixels SP, the first electrode AE may be electrically connected to the reflective electrode layer RL through the contact member CNP passing through (e.g., penetrating) the insulating layer INS.

For example, a portion of the insulating layer INS may be disposed under the (1-2)-th electrode AE2, and the (1-2)-th electrode AE2 may be electrically connected to the second reflective electrode layer RL2 through the contact member CNP passing through (e.g., penetrating) the insulating layer INS in the second sub-pixel area SPA2.

According to an embodiment, the first electrode AE may have a generally flat or substantially flat upper surface. The contact member CNP may be a structure inserted into a second hole H2 formed by the insulating layer INS, and at least a portion of the contact member CNP may extend in a direction (e.g., the third direction DR3 or a direction inclined to the first direction DR1 and the second direction DR2) different from a direction in which a plane where the substrate SUB is disposed extends (e.g., a direction in which a plane defined based on the first direction DR1 and the second direction DR2 extends). The contact member CNP may include a portion that extends toward the substrate SUB from a portion of the first electrode AE within the area where the light emitting element LD is formed in a plan view.

When a step by the insulating layer INS is not formed under the light emitting element LD from among the sub-pixels SP, the first electrode AE may form a direct electrical contact surface with the reflective electrode layer RL to be electrically connected to the reflective electrode layer RL.

For example, in some embodiments, the insulating layer INS may not be disposed under portions of the (1-1)-th electrode AE1 and the (1-3)-th electrode AE3 forming a first light emitting element LD1 and a second light emitting element LD2, and the portions of the (1-1)-th electrode AE1 and the (1-3)-th electrode AE3 forming a first light emitting element LD1 and a second light emitting element LD2 may form an electrical contact surface with the first and third reflective electrode layers RL1 and RL3 in the first and third sub-pixel areas SPA1 and SPA3, respectively.

According to an embodiment, the (1-1)-th electrode AE1 may be patterned in a first hole H1 formed in the insulating layer INS in the first sub-pixel area SPA1. The contact member CNP may be patterned in the second hole H2 formed in the insulating layer INS in the second sub-pixel area SPA2. The (1-3)-th electrode AE3 may be patterned in a third hole H3 formed in the insulating layer INS in the third sub-pixel area SPA3.

According to an embodiment, the first to third holes H1 to H3 may be patterned in the same process as each other, and thus, a thickness of the reflective electrode layer RL for each of the sub-pixels SP may be uniformly or substantially uniformly provided, and a risk that a partial reflective electrode layer RL is further etched due to an etching process for patterning the insulating layer INS may be reduced. This is described in more detail below with reference to FIG. 8.

Referring to FIG. 8, the first to third reflective electrode layers RL1 to RL3 electrically connected to the (1-1)-th electrode AE1, the (1-2)-th electrode AE2, and the (1-3)-th electrode AE3 in the first to third sub-pixels SP1 to SP3, respectively, are shown.

According to an embodiment, the (1-1)-th electrode AE1 may be disposed (e.g., directly disposed) on the first reflective electrode layer RL1. The contact member CNP may be disposed (e.g., directly disposed) on the second reflective electrode layer RL2. The (1-3)-th electrode AE3 may be disposed (e.g., directly disposed) on the third reflective electrode layer RL3.

Each of the first to third reflective electrode layers RL1 to RL3 may include a plurality of layers, and may include the uppermost conductive layer ML disposed at the uppermost portion of the plurality of layers.

The uppermost conductive layer ML may refer to a conductive layer most adjacent to the first electrode AE from among the plurality of conductive layers forming the reflective electrode layers RL. For example, when the reflective electrode layer RL includes the lower reflective electrode layer RL_L1, the intermediate reflective electrode layer RL_L2, and the upper reflective electrode layer RL_L3, the uppermost conductive layer ML may be the upper reflective electrode layer RL_L3.

The uppermost conductive layer ML of the first reflective electrode layer RL1 may contact the (1-1)-th electrode AE1. The uppermost conductive layer ML of the second reflective electrode layer RL2 may contact the contact member CNP which may be provided integrally with (e.g., formed integrally with) the (1-2)-th electrode AE2. The uppermost conductive layer ML of the third reflective electrode layer RL3 may contact the (1-3)-th electrode AE3.

The uppermost conductive layer ML of the reflective electrode layer RL may have a suitable thickness (e.g., a predetermined thickness). For example, the uppermost conductive layer ML of the first reflective electrode layer RL1 may have a first thickness T1. The uppermost conductive layer ML of the second reflective electrode layer RL2 may have a second thickness T2. The uppermost conductive layer ML of the third reflective electrode layer RL3 may have a third thickness T3.

According to an embodiment, the first thickness T1, the second thickness T2, and the third thickness T3 may be equal to or substantially equal to each other. Accordingly, the reflective electrode layers RL may have an intended thickness in each of the sub-pixels SP. For example, the first to third reflective electrode layers RL1 to RL3 may have the same or substantially the same thickness as each other.

According to an embodiment, the first electrodes AE may be directly disposed on some of the reflective electrode layers RL (e.g., the first reflective electrode layer RL1 and the third reflective electrode layer RL3). The contact member CNP may be directly disposed on another partial reflective electrode layer RL (e.g., the second reflective electrode layer RL2) without the first electrode AE being directly disposed. This structure may be provided as the insulating layer INS forms a step to form a resonance structure in some of the sub-pixels SP (e.g., the second sub-pixel SP2).

According to an embodiment, in the first and third sub-pixels SP1 and SP3, in order to electrically connect the first and third reflective electrode layers RL1 and RL3 to the (1-1)-th electrode AE1 and the (1-3)-th electrode AE3, the first and third holes H1 and H3 may be formed by generally removing the insulating layer INS on the first and third reflective electrode layers RL1 and RL3, and then the (1-1)-th electrode AE1 and the (1-3)-th electrode AE3 may be disposed on the first and third reflective electrode layers RL1 and RL3.

In the second sub-pixel SP2, in order to electrically connect the second reflective electrode layer RL2 to the (1-2)-th electrode AE2, the insulating layer INS may be formed on the second reflective electrode layer RL2, the second hole H2 may be formed in the insulating layer INS, and then the contact member CNP may be disposed on the second reflective electrode layer RL2 by patterning the (1-2)-th electrode AE2.

According to an embodiment, an etching process of forming the first to third holes H1 to H3 may be performed in the same process as each other to electrically connect the reflective electrode layers RL to the first electrodes AE. In this case, when the etching process of forming the first to third holes H1 to H3 is performed, the first to third reflective electrode layers RL1 to RL3 may be exposed, and an upper surface of the first to third reflective electrode layers RL1 to RL3 may or may not be uniformly affected by the etching process.

Accordingly, by the etching process of forming the first to third holes H1 to H3, a risk in a process, such as a thickness deviation of the first to third reflective electrode layers RL1 to RL3, which are a portion of a path through which the anode signal is supplied, may be reduced.

In addition, because a process of exposing the reflective electrode layer RL with respect to the sub-pixel SP in which the insulating layer INS forms a step forming structure may be performed with a process of exposing the reflective electrode layer RL with respect to the sub-pixel SP in which the insulating layer INS does not form a step forming structure in the same etching process as each other, the number of masks used may be reduced and process costs may be reduced.

According to an embodiment, because the first to third reflective electrode layers RL1 to RL3 may have an intended thickness characteristic, the first to third reflective electrode layers RL1 to RL3 may have an intended electrical characteristic (e.g., a resistance or the like). Therefore, a reliability of an electrical signal (e.g., the anode signal) for the light emitting element LD to emit light may be improved. In addition, because an anode voltage may be supplied to the light emitting element LD without distortion for each of the sub-pixels SP, a risk of a color deviation or the like for each of the sub-pixels SP may be reduced, thereby providing the display device 100 having excellent display quality.

In addition, in order for the display device 100 to have a high-resolution characteristic, a position where the layers of the display device 100 are patterned may be controlled in more detail (e.g., may be more finely controlled). According to an embodiment, because a mask for forming the second hole H2 (e.g., a mask for forming a via hole) may not be used or included, a risk that may be caused by a misalignment of a mask may be reduced.

Referring to FIG. 7, the pixel defining layer PDL may be disposed on the insulating layer INS. The pixel defining layer PDL may cover a portion of the first electrode AE. According to an embodiment, the pixel defining layer PDL may include an organic material or an inorganic material. For example, the pixel defining layer PDL may include a plurality of layers, each including an inorganic material, such as silicon oxide (SiOx), silicon nitride (SiNx), and/or silicon oxynitride (SiOxNy). However, the present disclosure is not limited thereto.

The trench TRCH may be disposed adjacent to the first electrode AE in a plan view. The trench TRCH may define a boundary area BDA between the sub-pixels SP, and may be disposed between adjacent first electrodes AE. The trench TRCH may cause a formation of a discontinuous portion (e.g., a discontinuity) in the emission structure EMS at the boundary area BDA. For example, at least a portion of the emission structure EMS may be disconnected or bent in the boundary area BDA due to the trench TRCH.

The trench TRCH may pass through the pixel defining layer PDL, and may pass through the insulating layer INS. According to an embodiment, the trench TRCH may further partially pass through a portion of the via layer VIAL.

According to an embodiment, the trench TRCH may have a depth of 200 nm to 1200 nm, and the trench TRCH may have a diameter or a width of 50 nm to 300 nm. According to an embodiment, the trench TRCH may have a depth of 200 nm to 700 nm, and the trench TRCH may have a diameter or a width of 100 nm to 200 nm. However, the present disclosure is not limited thereto.

The trench TRCH may include a void. As the trench TRCH forms the void, at least a portion of the emission structure EMS formed to cover the trench TRCH may be disconnected or bent. For example, at least a portion of layers that are commonly formed in the first to third sub-pixels SP1 to SP3 from among a plurality of layers included in the emission structure EMS may be disconnected. For example, a portion of a charge generation layer CGL (e.g., refer to FIG. 10) or the hole transport unit HTU included in the emission structure EMS may be disconnected by the trench TRCH.

The emission structure EMS may be disposed on the first electrode AE exposed by the pixel defining layer PDL, and may be disposed across the first to third sub-pixels SP1 to SP3. As described above, the emission structure EMS may be at least partially disconnected or bent in the boundary area BDA by the trench TRCH. Accordingly, a risk of a leakage current may be reduced, and the sub-pixels SP may have an operation characteristic having improved reliability.

The emission structure EMS may include a multiple layered structure electrically connected between the first electrode AE and the second electrode CE.

The emission structure EMS may include a light emitting unit (e.g., a light emitting device) EU including a plurality of layers. The light emitting unit EU may include a plurality of emission structures including the hole transport unit HTU, a light emitting layer (or a light generation layer) EML, and the electron transport unit ETU. Each of layers forming the emission structure may include an organic material, and according to an embodiment, may further include an inorganic material, such as a metal-containing compound or a quantum dot.

The hole transport unit HTU may include a multiple layered structure having a plurality of layers including different materials, respectively. As an example, the hole transport unit HTU may include a hole injection layer HIL and a hole transport layer HTL, and according to an embodiment, may further include a light emitting auxiliary layer, an electron blocking layer, and/or the like.

The light emitting layer EML may include a suitable material that may emit light of one color. The light emitting layer EML may include a host and a dopant. The host of the light emitting layer EML may be a light emitting material that may capture carriers (e.g., electrons and holes) for light generation, and may induce an exciton to be efficiently generated. The dopant may include a phosphorescent dopant or a fluorescent dopant. However, the examples of the dopant are not particularly limited thereto. According to an embodiment, the dopant may include an organic material, a metal complex material, or the like.

The electron transport unit ETU may include a multiple layered structure having a plurality of layers including different materials, respectively. The electron transport unit ETU may include an electron injection layer EIL and an electron transport layer ETL, and according to an embodiment, may further include an electron buffer layer, a hole blocking layer, and/or the like.

According to an embodiment, referring to FIG. 9, the emission structure EMS may include a single light emitting unit (e.g., a single light emitting device) EU. In this case, the emission structure EMS may include different materials in each of the sub-pixels SP. For example, the emission structure EMS may include a first emission structure disposed in the first sub-pixel SP1 and including a material for emitting light of a first color, a second emission structure disposed in the second sub-pixel SP2 and including a material for emitting light of a second color, and a third emission structure disposed in the third sub-pixel SP3 and including a material for emitting light of a third color.

According to an embodiment, referring to FIG. 10, the emission structure EMS may have a tandem structure. For example, the emission structure EMS may include a plurality of light emitting units (e.g., a plurality of light emitting devices) EU, and a charge generation layer CGL disposed between the plurality of light emitting units EU. The charge generation layer CGL may be disposed between the light emitting units EU to guide a current flow. In some embodiments, the charge generation layer CGL may have a stacked structure of a p dopant layer and an n dopant layer. According to an embodiment, the light emitting units EU may include a first light emitting unit (e.g., a first light emitting device) EU1 for providing the first color, a second light emitting unit (e.g., a second light emitting device) EU2 for providing the second color, and a third light emitting unit (e.g., a third light emitting device) EU3 for providing the third color. The charge generation layer CGL may include a first charge generation layer CGL1 and a second charge generation layer CGL2. According to an embodiment, in the emission structure EMS, the first light emitting unit EU1, the first charge generating layer CGL1, the second light emitting unit EU2, the second charge generating layer CGL2, and the third light emitting unit EU3 may be sequentially disposed.

The second electrode CE may be disposed on the emission structure EMS. The second electrode CE may be commonly provided to the first to third sub-pixels SP1 to SP3. The second electrode CE may function as a half mirror that partially transmits and partially reflects the light emitted from the emission structure EMS. However, the present disclosure is not limited thereto.

According to an embodiment, the first electrode AE, the emission structure EMS, and the second electrode CE may form the light emitting element LD. The light emitting element LD may include a first light emitting element LD1 forming the first sub-pixel SP1, a second light emitting element LD2 forming the second sub-pixel SP2, and a third light emitting element LD3 forming the third sub-pixel SP3.

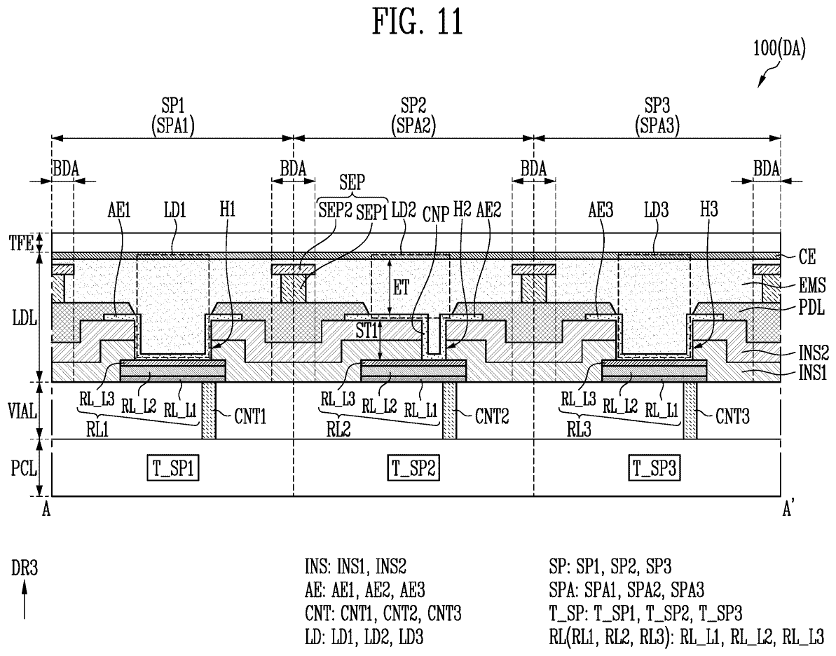

A display device 100 according to a second embodiment will be described in more detail below with reference to FIG. 11. Hereinafter with reference to FIG. 11, redundant description as those described above may not be repeated or may be briefly described.

FIG. 11 is a schematic cross-sectional view illustrating a display device according to the second embodiment. FIG. 11 illustrates a cross-sectional structure corresponding to that of FIG. 7, and illustrates a partial different structural characteristic of the display device 100.

Referring to FIG. 11, the display device 100 according to the second embodiment may be different from the display device 100 according to the first embodiment described above, in that the display device 100 according to the second embodiment may not include the trench TRCH. Instead, the display device 100 may further include a protruding separator SEP.

According to an embodiment, the display device 100 may further include the protruding separator SEP disposed on the pixel defining layer PDL, and disposed in the boundary area BDA.

The protruding separator SEP may include a plurality of layers. The number of layers forming the protruding separator SEP is not particularly limited. For convenience of illustration, FIG. 11 shows that the protruding separator SEP includes two layers. For example, the protruding separator SEP may include a first protruding separator SEP1 and a second protruding separator SEP2.

The second protruding separator SEP2 may be disposed on the first protruding separator SEP1, and may have a width greater than that of the first protruding separator SEP1. The width may be defined based on a direction in which adjacent sub-pixels SP are spaced apart from each other. Accordingly, the second protruding separator SEP2 may form a tip structure that protrudes with respect to the first protruding separator SEP1.

According to an embodiment, the first protruding separator SEP1 and the second protruding separator SEP2 may include an inorganic material. For example, the first protruding separator SEP1 and the second protruding separator SEP2 may include one or more of silicon oxide (SiOx) and/or silicon nitride (SiNx). However, the present disclosure is not limited thereto.

According to an embodiment, the emission structure EMS may be disposed across the first to third sub-pixels SP1 to SP3, and may be disposed on the protruding separator SEP. The protruding separator SEP may cause a formation of a discontinuity in the emission structure EMS in the boundary area BDA. For example, at least a portion of the emission structure EMS may be disconnected or bent in the boundary area BDA by the protruding separator SEP.

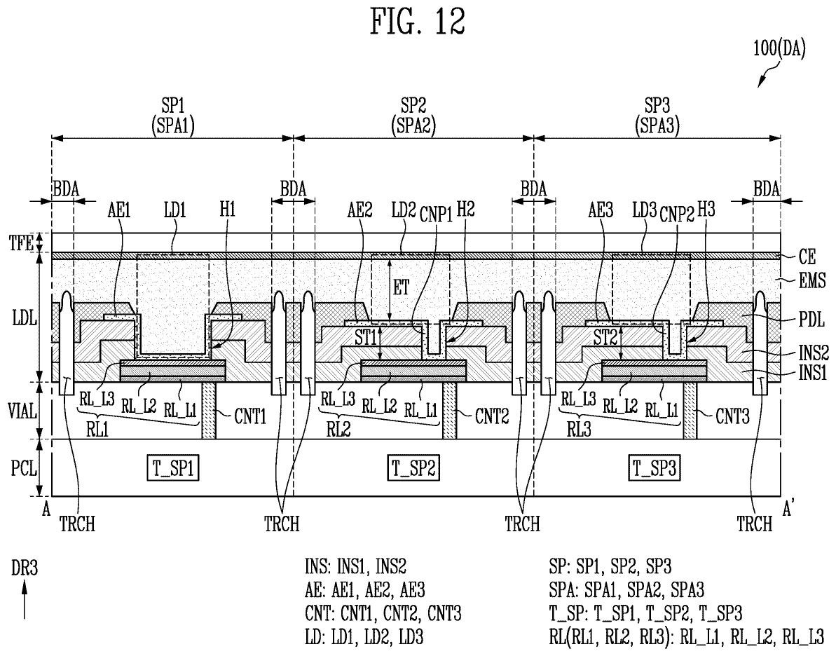

A display device 100 according to a third embodiment will be described in more detail below with reference to FIG. 12. Hereinafter with reference to FIG. 12, redundant description as those described above may not be repeated or may be briefly described.

FIG. 12 is a schematic cross-sectional view illustrating a display device according to the third embodiment. FIG. 12 illustrates a cross-sectional structure corresponding to that of FIG. 7, and illustrates a partial different structural characteristic of the display device 100.

Referring to FIG. 12, the display device 100 according to the third embodiment may be different from the display device 100 according to the first embodiment described above, in that the insulating layer INS may form a step for the third light emitting element LD3 in the third sub-pixel area SPA3.

According to an embodiment, the contact member CNP may include a first contact member CNP1 electrically connecting the (1-2)-th electrode AE2 and the second reflective electrode layer RL2 to each other, and a second contact member CNP2 electrically connecting the (1-3)-th electrode AE3 and the third reflective electrode layer RL3 to each other.

The first and second contact members CNP1 and CNP2 may have the same or substantially the same characteristic as that of the contact member CNP described above with reference to the first embodiment.

For example, at least a portion of the insulating layer INS may be disposed between the third reflective electrode layer RL3 and the (1-3)-th electrode AE3, and the second contact member CNP2 may be disposed in the third hole H3 in the third sub-pixel area SPA3. The second contact member CNP2 may contact the third reflective electrode layer RL3 in an area exposed by the insulating layer INS (e.g., exposing) the third reflective electrode layer RL3.

According to an embodiment, the first electrode AE may have a thickness of 25 nm to 35 nm.

According to an embodiment, the lower reflective electrode layer RL_L1 may have a thickness of 8 nm to 12 nm. The intermediate reflective electrode layer RL_L2 may have a thickness of 45 nm to 55 nm. The upper reflective electrode layer RL_L3 may have a thickness of 8 nm to 12 nm.

According to an embodiment, the insulating layer INS may form a step in the second sub-pixel SP2 and the third sub-pixel SP3, and based on the step formed by the insulating layer INS, a resonance distance may be determined in the second and third sub-pixels SP2 and SP3.

According to an embodiment, in the second sub-pixel SP2, the insulating layer INS may form a step having a first step thickness ST1 between the (1-2)-th electrode AE2 and the second reflective electrode layer RL2. In the third sub-pixel SP3, the insulating layer INS may form a step having a second step thickness ST2 between the (1-3)-th electrode AE3 and the third reflective electrode layer RL3.

According to an embodiment, each of the first and second step thicknesses ST1 and ST2 and the thickness of the emission structure EMS may have a suitable numerical range (e.g., a predetermined numerical range). For example, the emission thickness ET of the emission structure EMS may be 620 nm to 660 nm. According to an embodiment, the emission thickness ET of the emission structure EMS may be about 642 nm. The first step thickness ST1 may be 35 nm to 55 nm, and the second step thickness ST2 may be 35 nm to 55 nm. As another example, the first step thickness ST1 may be 40 nm to 50 nm, and the second step thickness ST2 may be 40 nm to 50 nm. According to an embodiment, the first step thickness ST1 and the second step thickness ST2 may be equal to or substantially equal to each other. For example, the first step thickness ST1 may be about 40 nm, and the second step thickness ST2 may be about 40 nm.

According to an embodiment, when the first and second step thicknesses ST1 and ST2 satisfy the above-described numerical range, a light emission efficiency of the first to third sub-pixels SP1 to SP3 may have generally uniformly excellent efficiency. In addition, according to an embodiment, the first step thickness ST1 and the second step thickness ST2 may be equal to or substantially equal to each other, and thus, a process convenience may be further improved.

According to an embodiment, an etching process for forming the first to third holes H1 to H3 may be performed in the same process as each other.

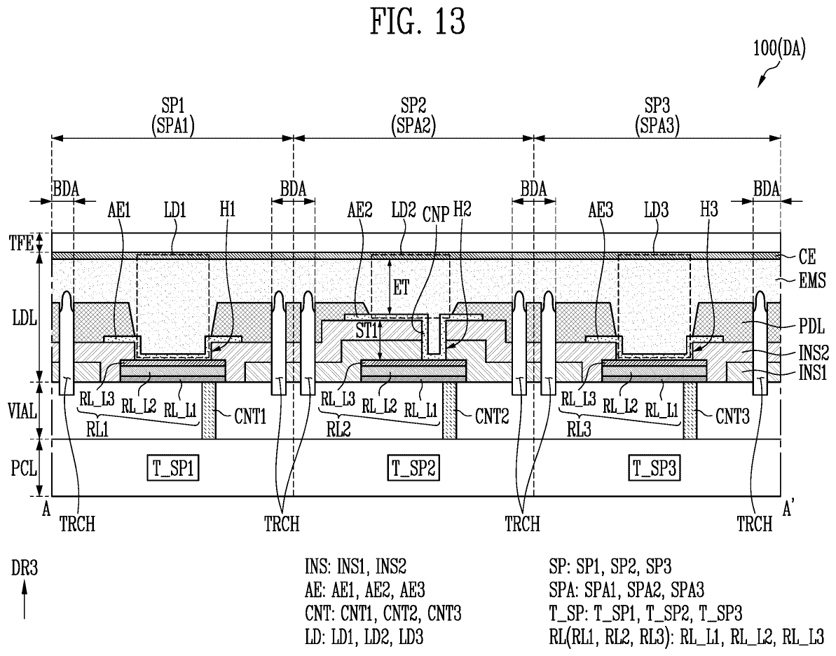

A display device 100 according to a fourth embodiment will be described in more detail below with reference to FIG. 13. Hereinafter with reference to FIG. 13, redundant description as those described above may not be repeated or may be briefly described.

FIG. 13 is a schematic cross-sectional view illustrating a display device according to the fourth embodiment. FIG. 13 illustrates a cross-sectional structure corresponding to that of FIG. 7, and illustrates a partial different structural characteristic of the display device 100.

Referring to FIG. 13, the display device 100 according to the fourth embodiment may be different from the display device 100 according to the first embodiment described above, in that the first insulating layer INS1 may not cover the first and third reflective electrode layers RL1 and RL3.

According to an embodiment, the first insulating layer INS1 may expose the upper surface and the side surfaces of each of the first reflective electrode layer RL1 and the third reflective electrode layer RL3. For example, the first insulating layer INS1 may be spaced apart from the first reflective electrode layer RL1 and the third reflective electrode layer RL3. The second insulating layer INS2 may cover the upper surface and the side surfaces of each of the first reflective electrode layer RL1 and the third reflective electrode layer RL3.

The first insulating layer INS1 may not define the first and third holes H1 and H3 exposing the first and third reflective electrode layers RL1 and RL3, and the first and third holes H1 and H3 may be defined by the second insulating layer INS2. In this case, an etching process for forming the first and third holes H1 and H3 may be performed on (e.g., only on) the second insulating layer INS2 rather than on the first insulating layer INS1, and thus, a precision of a process for forming the first and third holes H1 and H3 may be further improved.

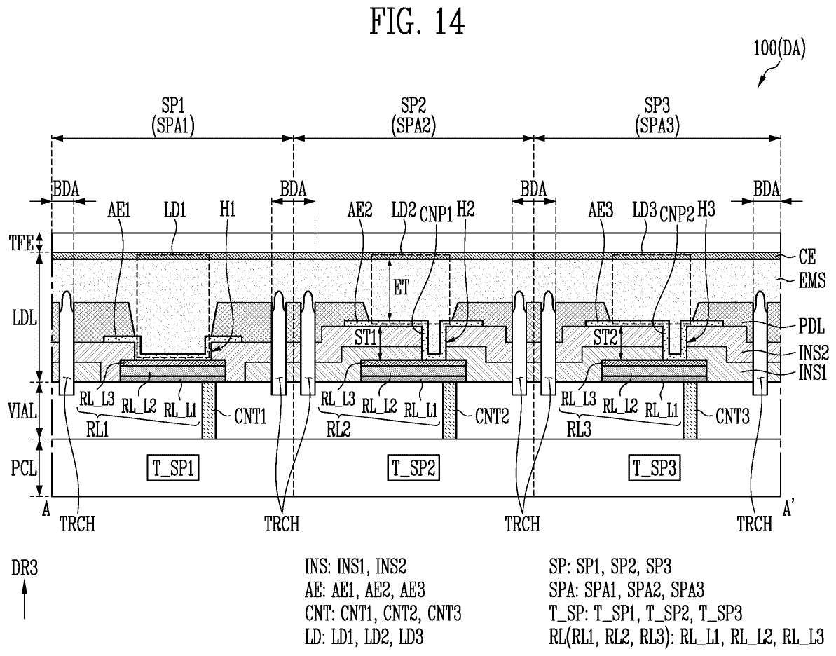

A display device 100 according to a fifth embodiment will be described in more detail below with reference to FIG. 14. Hereinafter with reference to FIG. 14, redundant description as those described above may not be repeated or may be briefly described.

FIG. 14 is a schematic cross-sectional view illustrating a display device according to the fifth embodiment. FIG. 14 illustrates a cross-sectional structure corresponding to that of FIG. 7, and illustrates a partial different structural characteristic of the display device 100.

Referring to FIG. 14, the display device 100 according to the fifth embodiment may be different from the display device 100 according to the third embodiment described above with reference to FIG. 12, in that the first insulating layer INS1 may not cover the first reflective electrode layer RL1.

According to an embodiment, the first insulating layer INS1 may expose the upper surface and the side surfaces of each first reflective electrode layer RL1. For example, the first insulating layer INS1 may be spaced apart from the first reflective electrode layer RL1. The second insulating layer INS2 may cover the upper surface and the side surfaces of each first reflective electrode layer RL1.

The first insulating layer INS1 may not define the first hole H1 exposing the first reflective electrode layers RL1, and the first hole H1 may be defined by the second insulating layer INS2. In this case, an etching process for forming the first hole H1 may be performed on (e.g., only on) the second insulating layer INS2 rather than on the first insulating layer INS1, and thus, a precision of a process for forming the first hole H1 may be further improved.

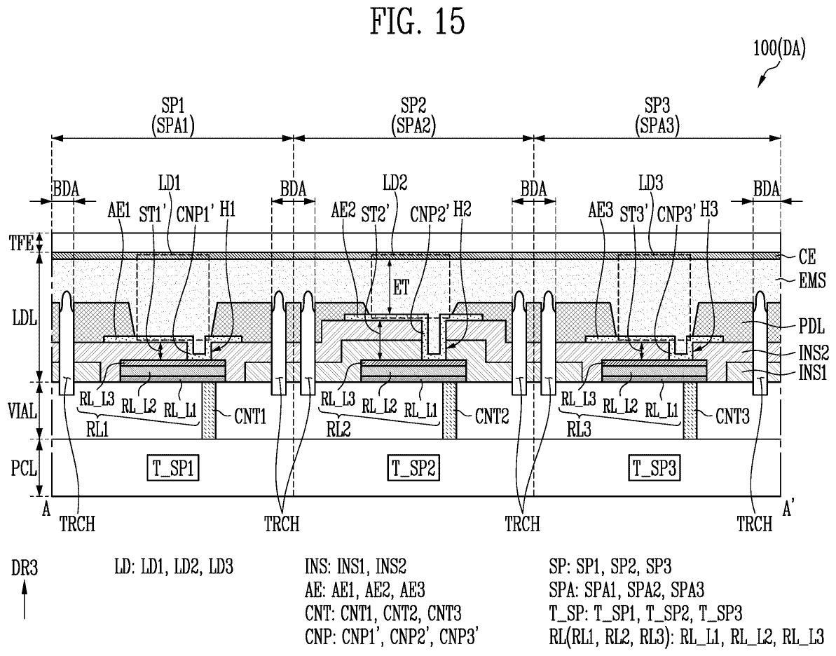

A display device 100 according to a sixth embodiment will be described in more detail below with reference to FIG. 15. Hereinafter with reference to FIG. 15, redundant description as those described above may not be repeated or may be briefly described.

FIG. 15 is a schematic cross-sectional view illustrating the display device according to the sixth embodiment. FIG. 15 illustrates a cross-sectional structure corresponding to that of FIG. 7, and illustrates a partial different structural characteristic of the display device 100.

Referring to FIG. 15, the display device 100 according to the sixth embodiment may be different from the display device 100 described above, in that the insulating layer INS may form a step under the first electrode AE of each of the first to third sub-pixels SP1 to SP3.

According to an embodiment, the insulating layer INS (e.g., the second insulating layer INS2) may be disposed between the (1-1)-th electrode AE1 and the first reflective electrode layer RL1, and may form a step. According to an embodiment, the (1-1)-th electrode AE1 may not directly contact the upper surface of the first reflective electrode layer RL1, and may be electrically connected to the first reflective electrode layer RL1 through a first contact member CNP1′.

According to an embodiment, the insulating layer INS (e.g., the first insulating layer INS1 and the second insulating layer INS2) may be disposed between the (1-2)-th electrode AE2 and the second reflective electrode layer RL2, and may form a step. According to an embodiment, the (1-2)-th electrode AE2 may not directly contact the upper surface of the second reflective electrode layer RL2, and may be electrically connected to the second reflective electrode layer RL2 through a second contact member CNP2′.

According to an embodiment, the insulating layer INS (e.g., the second insulating layer INS2) may be disposed between the (1-3)-th electrode AE3 and the third reflective electrode layer RL3, and may form a step. According to an embodiment, the (1-3)-th electrode AE3 may not directly contact the upper surface of the third reflective electrode layer RL3, and may be electrically connected to the third reflective electrode layer RL3 through a third contact member CNP3′.

According to an embodiment, the first to third contact members CNP1′ to CNP3′ may be provided in the first to third holes H1 to H3, respectively. According to an embodiment, the first to third holes H1 to H3 may be formed in the same process while the insulating layer INS forming a step is provided to each of the sub-pixels SP. Accordingly, similarly to the embodiments described above, the uppermost conductive layers ML of each of the first to third reflective electrode layers RL1 to RL3 may have a uniform or substantially uniform thickness for each of the sub-pixels SP. Accordingly, the sub-pixels SP may emit light based on an intended electrical characteristic, and a reliability of a light signal may be improved.

According to an embodiment, the insulating layer INS of the first sub-pixel SP1 may form a step having a first step thickness ST1′ between the (1-1)-th electrode AE1 and the first reflective electrode layer RL1. According to an embodiment, the insulating layer INS of the second sub-pixel SP2 may form a step having a second step thickness ST2′ between the (1-2)-th electrode AE2 and the second reflective electrode layer RL2. According to an embodiment, the insulating layer INS of the third sub-pixel SP3 may form a step having a third step thickness ST3′ between the (1-3)-th electrode AE3 and the third reflective electrode layer RL3.

According to an embodiment, each of the first to third step thicknesses ST1′ to ST3′ may have a suitable numerical range (e.g., a predetermined numerical range).

For example, the first step thickness ST1′ may be 125 nm to 165 nm. As another example, the first step thickness ST1′ may be 135 nm to 155 nm. According to an embodiment, the first step thickness ST1′ may be about 145 nm. The second step thickness ST2′ may be 320 nm to 380 nm. As another example, the second step thickness ST2′ may be 330 nm to 370 nm. According to an embodiment, the second step thickness ST2′ may be about 350 nm. The third step thickness ST3′ may be 125 nm to 165 nm. As another example, the third step thickness ST3′ may be 135 nm to 155 nm. According to an embodiment, the third step thickness ST3′ may be about 145 nm. However, the present disclosure is not limited thereto.

According to an embodiment, when the first to third step thicknesses ST1′ to ST3′ satisfy the above-described numerical range, a light emission efficiency of the first to third sub-pixels SP1 to SP3 may have generally uniformly excellent efficiency.

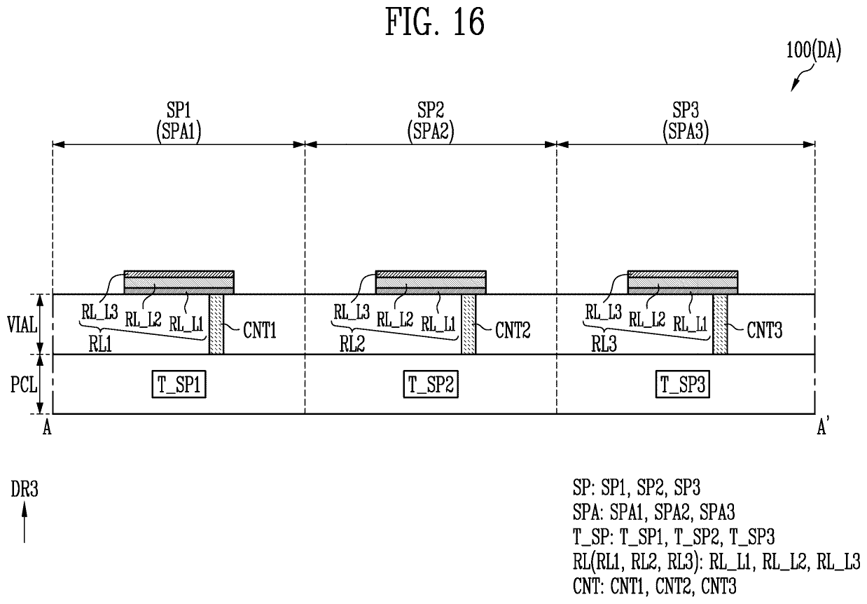

A method of manufacturing a display device 100 according to some embodiments will be described in more detail below with reference to FIGS. 16 to 31.

FIGS. 16 through 31 are schematic cross-sectional views for processes of a method of manufacturing a display device according to some embodiments.

First, a method of manufacturing the display device 100 according to the first and second embodiments will be described in more detail with reference to FIGS. 16 to 23. Hereinafter with reference to FIGS. 12 to 23, redundant description as those described above may be briefly described, or may not be repeated.

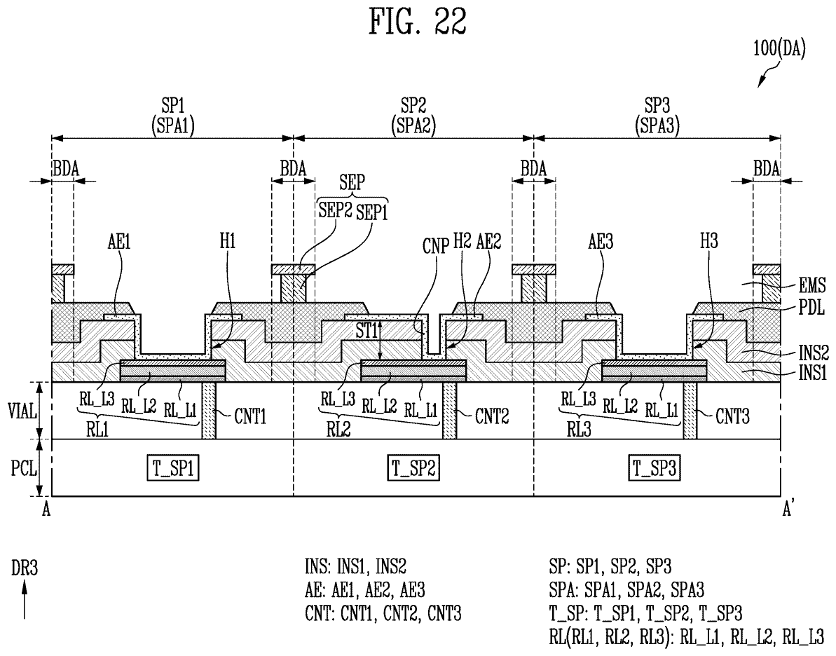

FIGS. 16 to 21 and FIG. 23 schematically illustrate the method of manufacturing the display device 100 according to the first embodiment. FIG. 22 schematically illustrates the method of manufacturing the display device 100 according to the second embodiment. For convenience of illustration, FIGS. 12 to 23 are shown based on the cross-sectional structure described above with reference to FIG. 7.

Referring to FIG. 16, the substrate SUB may be provided, and the circuit elements (e.g., the first to third transistors T_SP1 to T_SP3) may be patterned. In addition, the via layer VIAL may be formed on the pixel-circuit layer PCL, the reflective electrode layers RL may be patterned on the via layer VIAL, and the reflective electrode layers RL may be electrically connected to the circuit elements of the pixel-circuit layer PCL through the contact portion CNT.

According to an embodiment, a conductive layer or an insulating layer on the substrate SUB may be formed based on a suitable process for manufacturing a semiconductor device. For example, the conductive layer or the insulating layer on the substrate SUB may be formed by a photolithography process, etched by various suitable methods (e.g., wet etching, dry etching, and the like), and may be deposited by various suitable methods (e.g., sputtering, chemical vapor deposition method, and the like). However, the present disclosure is not necessarily limited thereto.

In FIG. 16, the first to third reflective electrode layers RL1 to RL3 may be patterned in the first to third sub-pixel areas SPA1 to SPA3, respectively, and the first to third reflective electrode layers RL1 to RL3 may be electrically connected to the first to third transistors T_SP1 to T_SP3 through the first to third contact portions CNT1 to CNT3.

In order to form the reflective electrode layer RL, the lower reflective electrode layer RL_L1, the intermediate reflective electrode layer RL_L2, and the upper reflective electrode layer RL_L3 may be sequentially formed.

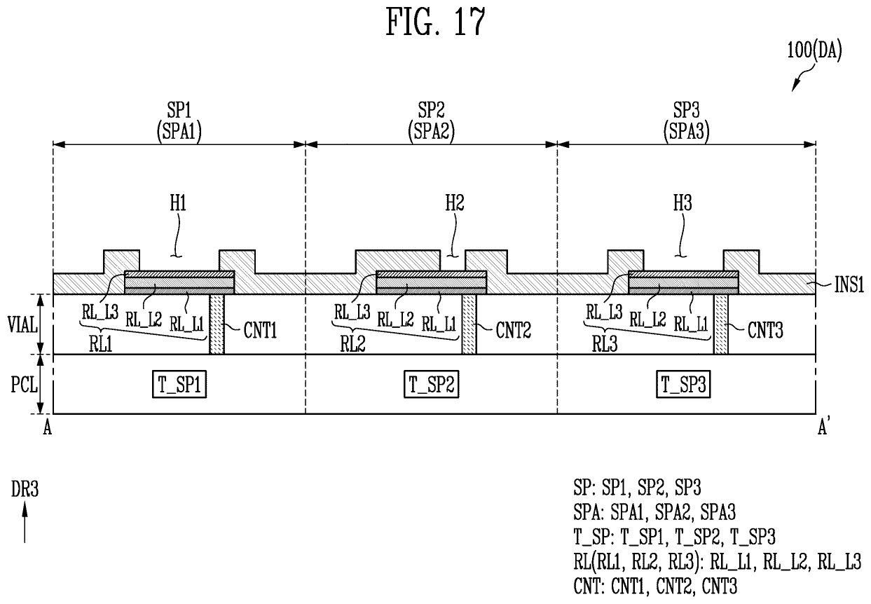

Referring to FIG. 17, the first insulating layer INS1 may be patterned.

In FIG. 17, the first insulating layer INS1 may be patterned to expose at least a portion of each of the first to third reflective electrode layers RL1 to RL3. For example, the first insulating layer INS1 may form the first hole H1 exposing the first reflective electrode layer RL1, may form a second hole H2 exposing the second reflective electrode layer RL2, and may form the third hole H3 exposing the third reflective electrode layer RL3.

The first and third holes H1 and H3 may have a diameter greater than that of the second hole H2. According to an embodiment, the first insulating layer INS1 may generally expose the first and third reflective electrode layers RL1 and RL3, may generally cover the second reflective electrode layer RL2, and may expose a portion of the second reflective electrode layer RL2. Accordingly, the first and third holes H1 and H3 may form an area where the (1-1)-th electrode AE1 and the (1-3)-th electrode AE3 are disposed, and the second hole H2 may form an area where the contact member CNP is disposed as a via hole.

The first insulating layer INS1 may form a portion of a step forming structure on the second reflective electrode layer RL2.

As the first insulating layer INS1 is patterned, the first to third holes H1 to H3 may be formed concurrently or substantially simultaneously with each other. An etching process for patterning the first insulating layer INS1 may be equally applied to each of the first to third sub-pixels SP1 to SP3. Accordingly, as described above, the etching process may or may not affect the first to third reflective electrode layers RL1 to RL3 identically, and a reliability for an electrical signal in the display device 100 may be improved.

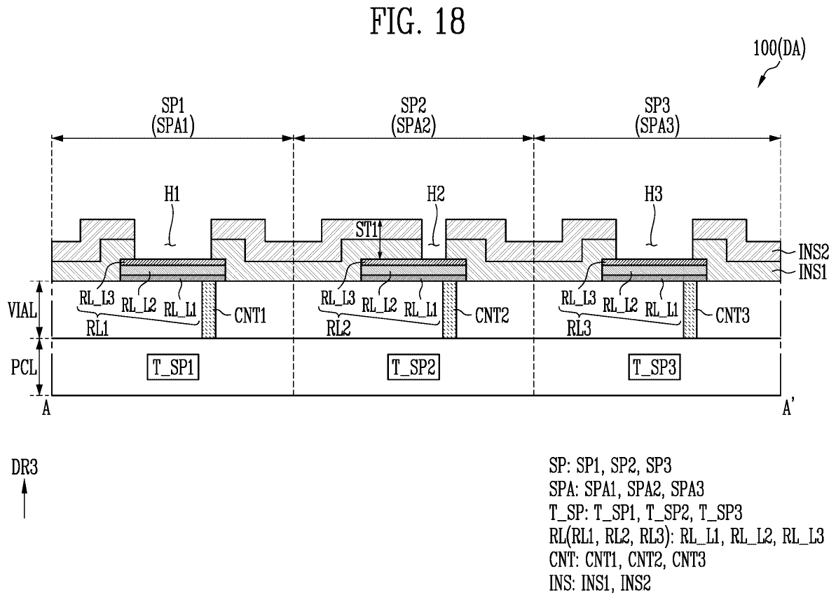

Referring to FIG. 18, the second insulating layer INS2 may be patterned.

In FIG. 18, the second insulating layer INS2 may be patterned to form the first to third holes H1 to H3 together with the first insulating layer INS1, and expose at least a portion of each of the first to third reflective electrode layers RL1 to RL3.

The insulating layer INS including the first insulating layer INS1 and the second insulating layer INS2 may form the second hole H2, which is the via hole, and may form a step portion having the first step thickness ST1. The insulating layer INS including the first insulating layer INS1 and the second insulating layer INS2 may form the first and third holes H1 and H3 for disposing the (1-1)-th electrode AE1 and the (1-3)-th electrode AE3, and may not form a portion forming a step on the first and third reflective electrode layers RL1 and RL3.

As the second insulating layer INS2 is patterned, the first to third holes H1 to H3 may be formed concurrently or substantially simultaneously with each other. An etching process for patterning the second insulating layer INS2 may be equally applied to each of the first to third sub-pixels SP1 to SP3. Accordingly, as described above, the etching process may or may not affect the first to third reflective electrode layers RL1 to RL3 identically, and a reliability for an electrical signal in the display device 100 may be improved.

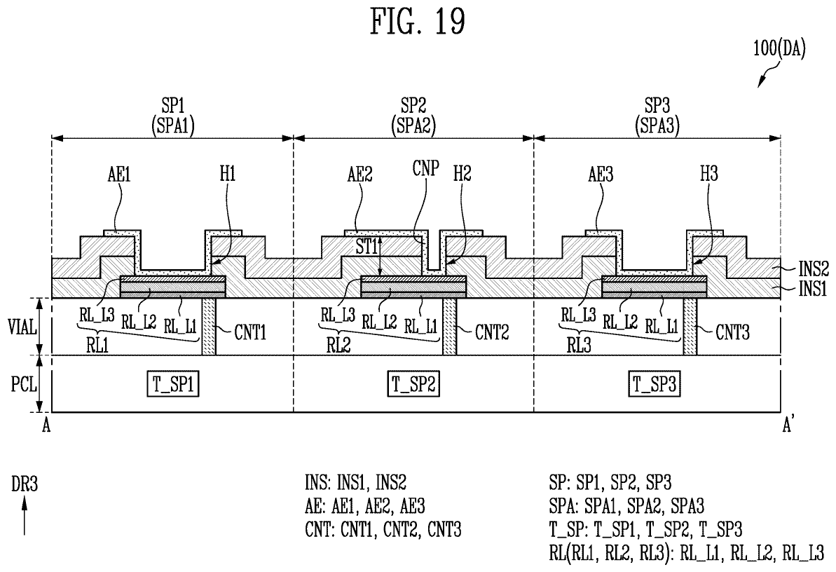

Referring to FIG. 19, the first electrodes AE may be patterned.

In FIG. 19, the (1-1)-th electrode AE1, the (1-2)-th electrode AE2, and the (1-3)-th electrode AE3 may be patterned to be electrically connected to the first to third reflective electrode layers RL1 to RL3. For example, the (1-1)-th electrode AE1 may be disposed in the first hole H1, and may be electrically connected to the first reflective electrode layer RL1. The (1-2)-th electrode AE2 may be disposed on the insulating layer INS, and the contact member CNP may be disposed in the second hole H2, and thus, the (1-2)-th electrode AE2 may be electrically connected to the second reflective electrode layer RL2 through the contact member CNP. The (1-3)-th electrode AE3 may be disposed in the third hole H3, and may be electrically connected to the third reflective electrode layer RL3.

The (1-1)-th electrode AE1 may be directly disposed on the first reflective electrode layer RL1 in the first hole H1, the (1-2)-th electrode AE2 may be directly disposed on the insulating layer INS without being disposed in the second hole H2, and the (1-3)-th electrode AE3 may be directly disposed on the third reflective electrode layer RL3 in the third hole H3.

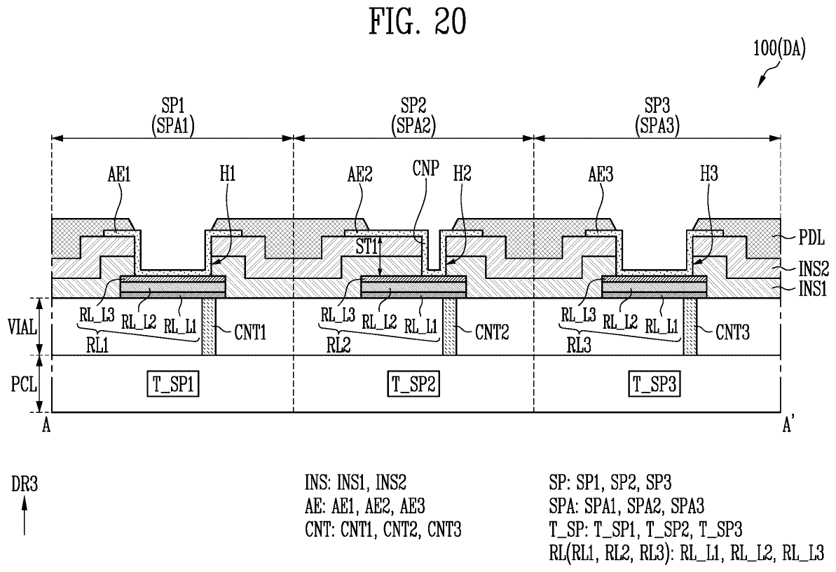

Referring to FIG. 20, the pixel defining layer PDL may be patterned.

In FIG. 20, the pixel defining layer PDL may be patterned to expose at least the (1-1)-th electrode AE1, the (1-2)-th electrode AE2, and the (1-3)-th electrode AE3.

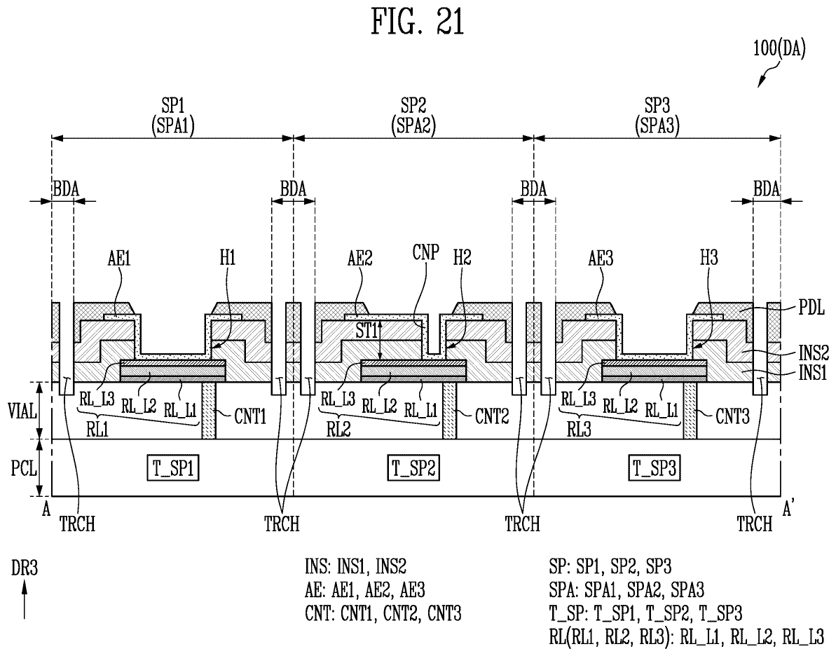

Referring to FIG. 21, the trench TRCH passing through (e.g., penetrating) the pixel defining layer PDL may be formed according to an embodiment.

In FIG. 21, an etching process may be performed so that the trench TRCH passes through (e.g., penetrates) the pixel defining layer PDL and the insulating layer INS. According to an embodiment, an etching process may be performed so that the trench TRCH partially further passes through (e.g., penetrates) a portion of the via layer VIAL. The number of trenches TRCH in the boundary area BDA is not particularly limited.

As another example, according to an embodiment, referring to FIG. 22, the protruding separator SEP may be patterned on the pixel defining layer PDL. In this case, the trench TRCH may not be formed. When the protruding separator SEP including the tip structure is formed, and the emission structure EMS is formed in subsequent processes, at least a portion of the emission structure EMS may be disconnected.

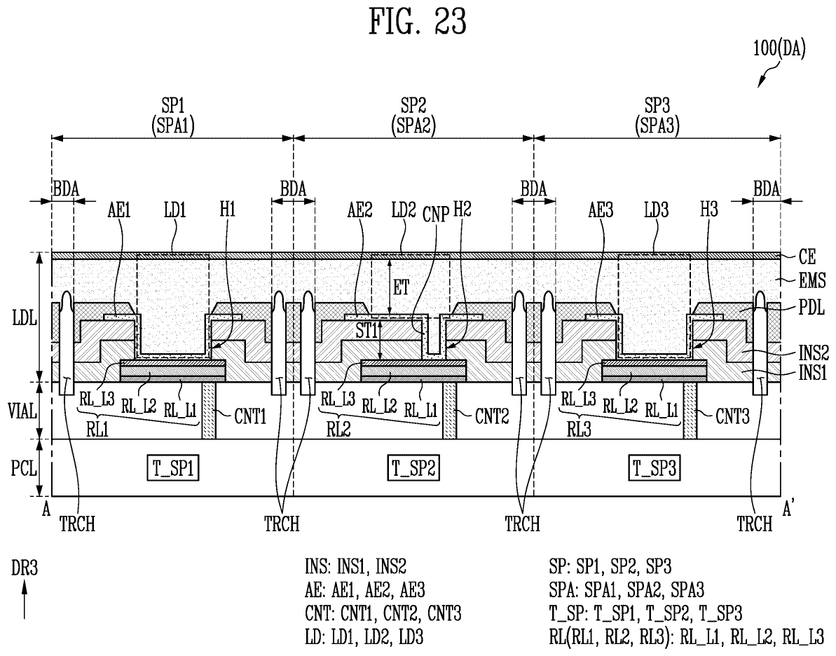

Referring to FIG. 23, the emission structure EMS may be formed across the first to third sub-pixels SP1 to SP3, and the second electrode CE may be formed on the emission structure EMS.

In FIG. 23, the emission structure EMS may be formed across the boundary area BDA. The emission structure EMS may be formed based on various suitable methods, such as deposition and coating. Accordingly, at least a portion of the emission structure EMS may be disconnected by the trench TRCH or the protruding separator SEP, and a risk of a leakage current between adjacent sub-pixels SP may be reduced.

As the second electrode CE is entirely deposited, the second electrode CE may function as a common electrode for the first to third sub-pixels SP1 to SP3, and the first to third light emitting elements LD1 to LD3 may be provided.

Thereafter, according to an embodiment, the encapsulation layer TFE may be disposed, additional layers may be disposed on the encapsulation layer TFE, and the display device 100 may be provided.

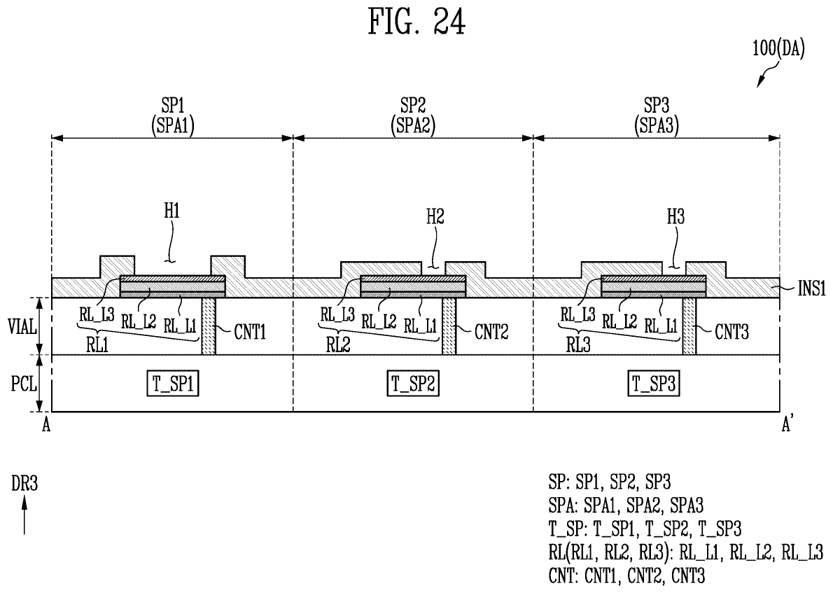

Next, with reference to FIGS. 24 to 27, a method of manufacturing the display device 100 according to the third embodiment will be described in more detail. Hereinafter with reference to FIGS. 24 to 27, redundant description as those described above may be briefly described, or may not be repeated.

FIGS. 24 to 27 schematically illustrate a method of manufacturing the display device 100 according to the third embodiment. For convenience of illustration, FIGS. 24 to 27 are shown based on the cross-sectional structure described above with reference to FIG. 12.

Referring to FIG. 24, the process described above with reference to FIG. 16 may be performed, and the first insulating layer INS1 may be patterned.

In FIG. 24, the first insulating layer INS1 may form the first hole H1 exposing the first reflective electrode layer RL1, may form the second hole H2 exposing the second reflective electrode layer RL2, and may form the third hole H3 exposing the third reflective electrode layer RL3. The first insulating layer INS1 may further form a step forming structure in the third sub-pixel area SPA3. For example, the first hole H1 may form an area where the (1-1)-th electrode AE1 is disposed, and the second and third holes H2 and H3 may form an area where the contact member CNP is disposed as via holes.

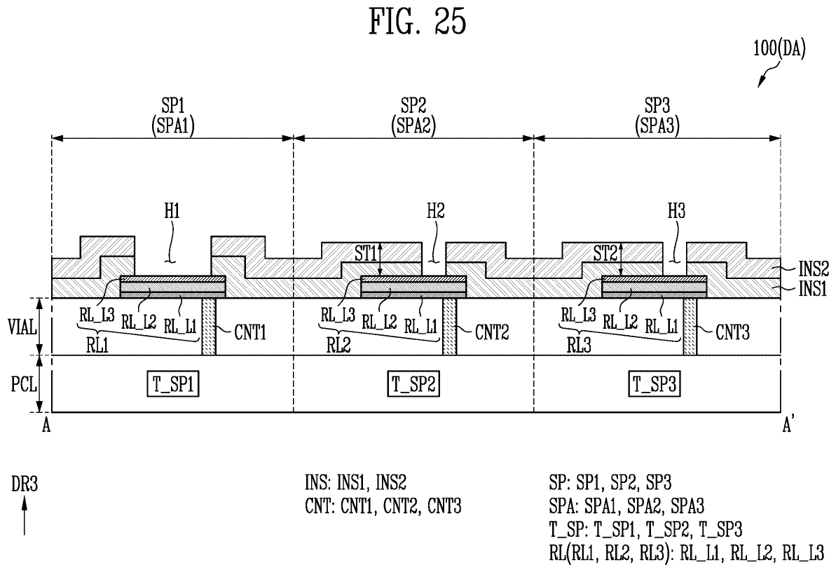

Referring to FIG. 25, the second insulating layer INS2 may be patterned.

In FIG. 25, the second insulating layer INS2 may be patterned to form the first to third holes H1 to H3 together with the first insulating layer INS1, and may expose at least a portion of each of the first to third reflective electrode layers RL1 to RL3.

The insulating layer INS including the first insulating layer INS1 and the second insulating layer INS2 may form the second and third holes H2 and H3, which are via holes, and may form step portions having the first and second step thicknesses ST1 and ST2, respectively. The insulating layer INS including the first insulating layer INS1 and the second insulating layer INS2 may form the first hole H1 for disposing the (1-1)-th electrode AE1, and may not form a step forming structure on the first reflective electrode layer RL1.

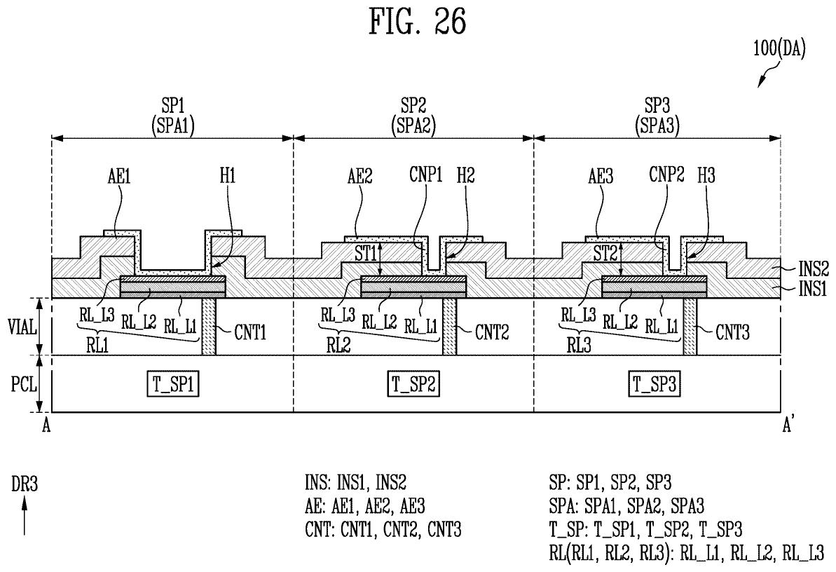

Referring to FIG. 26, the first electrodes AE may be patterned.

In FIG. 26, the (1-1)-th electrode AE1, the (1-2)-th electrode AE2, and the (1-3)-th electrode AE3 may be patterned to be electrically connected to the first to third reflective electrode layers RL1 to RL3. For example, the (1-1)-th electrode AE1 may be disposed in the first hole H1, and may be electrically connected to the first reflective electrode layer RL1. The (1-2)-th electrode AE2 may be disposed on the insulating layer INS, and the first contact member CNP1 may be disposed in the second hole H2, and thus, the (1-2)-th electrode AE2 may be electrically connected to the second reflective electrode layer RL2 through the first contact member CNP1. The (1-3)-th electrode AE3 may be disposed on the insulating layer INS, and the second contact member CNP2 may be disposed in the third hole H3, and thus, the (1-3)-th electrode AE3 may be electrically connected to the third reflective electrode layer RL3 through the second contact member CNP2.

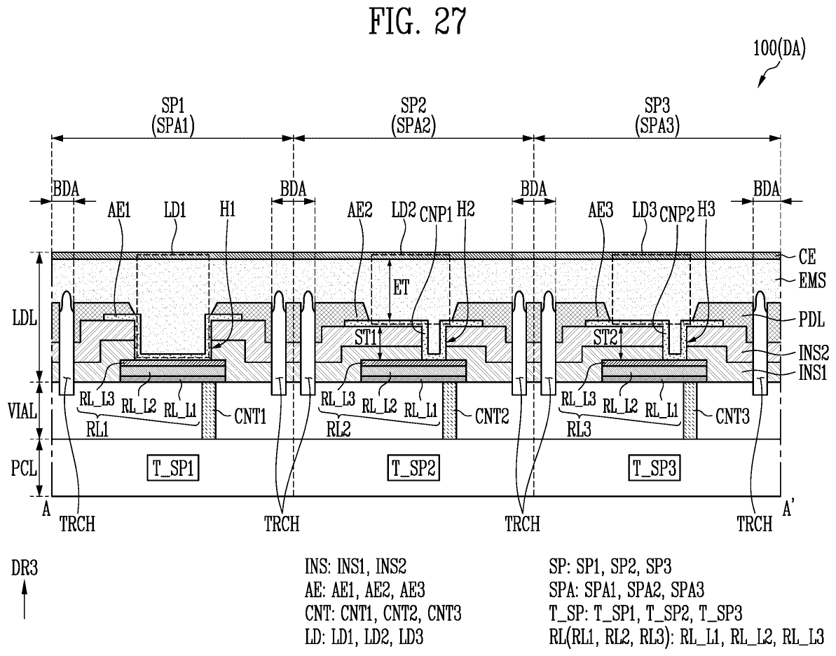

Referring to FIG. 27, the pixel defining layer PDL exposing the (1-1)-th electrode AE1, the (1-2)-th electrode AE2, and the (1-3)-th electrode AE3 may be patterned, and the emission structure EMS and the second electrode CE may be disposed. Accordingly, the first to third light emitting elements LD1 to LD3 may be provided.

Thereafter, according to an embodiment, the encapsulation layer TFE May be disposed, additional layers may be disposed on the encapsulation layer TFE, and the display device 100 may be provided.

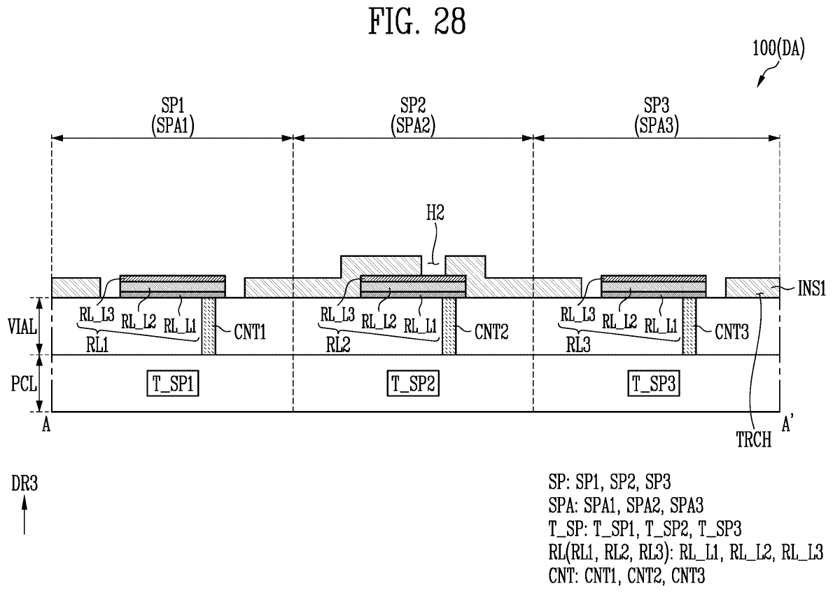

Next, with reference to FIGS. 28 to 31, a method of manufacturing the display device 100 according to the sixth embodiment will be described in more detail. Hereinafter with reference to FIGS. 28 to 31, redundant description as those described above may not be repeated or may be briefly described.

FIGS. 28 to 31 schematically illustrates the method of manufacturing the display device 100 according to the sixth embodiment. For convenience of illustration, FIGS. 28 to 31 are shown based on the cross-sectional structure described above with reference to FIG. 15.

Referring to FIG. 28, the process described above with reference to FIG. 16 may be performed, and the first insulating layer INS1 may be patterned.

In FIG. 28, the first insulating layer INS1 may expose the first reflective electrode layer RL1, may form the second hole H2 exposing the second reflective electrode layer RL2, and may expose the third reflective electrode layer RL3. The first insulating layer INS1 may form a step forming structure in the second sub-pixel area SPA2.

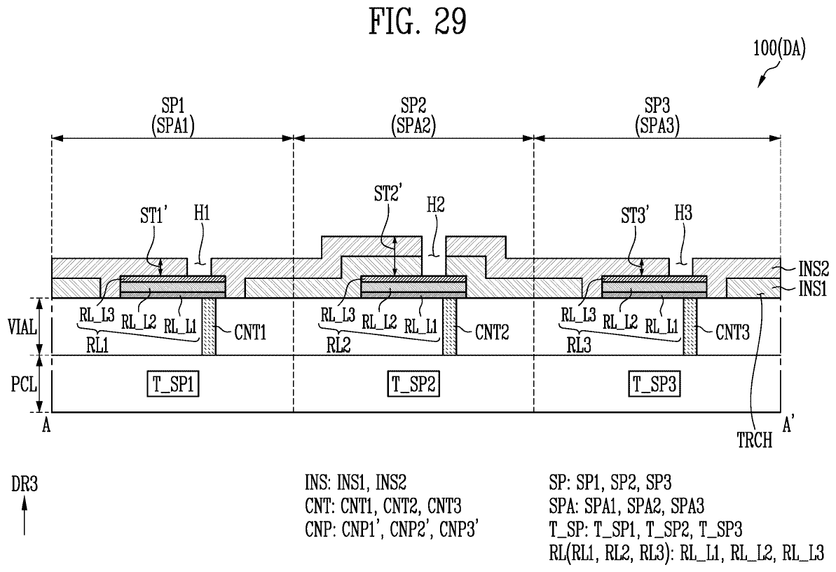

Referring to FIG. 29, the second insulating layer INS2 may be patterned.

In FIG. 29, the second insulating layer INS2 may form the first hole H1 exposing the first reflective electrode layer RL1 in the first sub-pixel area SPA1, may form the second hole H2 exposing the second reflective electrode layer RL2 together with the first insulating layer INS1 in the second sub-pixel area SPA2, and may form the third hole H3 exposing the third reflective electrode layer RL3 in the third sub-pixel area SPA3. According to an embodiment, the first to third holes H1 to H3 may form an area where the first to third contact members CNP1′ to CNP3′ are disposed as via holes.

The insulating layer INS including the first insulating layer INS1 and the second insulating layer INS2 may form the first to third holes H1 to H3, which are via holes, and may form step portions respectively having the first to third step thicknesses ST1′ to ST3′.

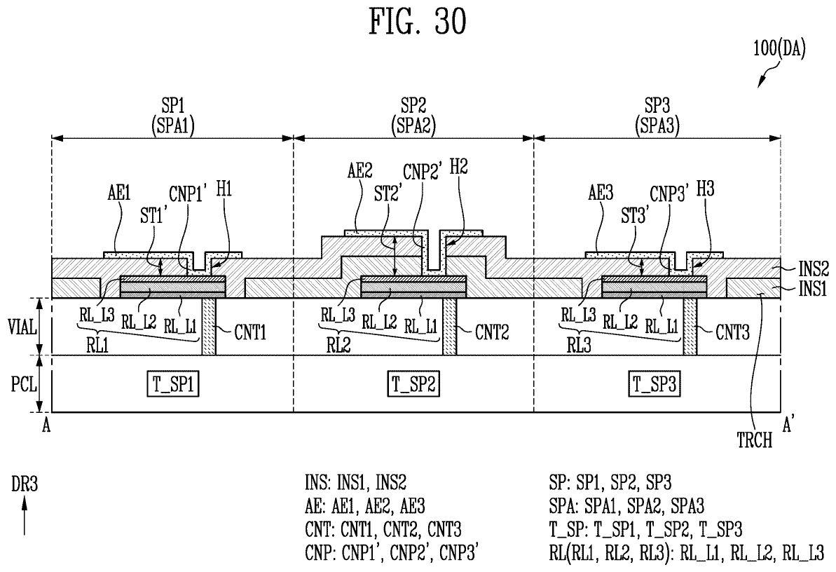

Referring to FIG. 30, the first electrodes AE may be patterned.

In FIG. 30, the (1-1)-th electrode AE1, the (1-2)-th electrode AE2, and the (1-3)-th electrode AE3 may be patterned to be electrically connected to the first to third reflective electrode layers RL1 to RL3. For example, the (1-1)-th electrode AE1 may be disposed on the insulating layer INS, and the first contact member CNP1′ may be disposed in the first hole H1, and thus, the (1-1)-th electrode AE1 may be electrically connected to the first reflective electrode layer RL1 through the first contact member CNP1′. The (1-2)-th electrode AE2 may be disposed on the insulating layer INS, and the second contact member CNP2′ may be disposed in the second hole H2, and thus, the (1-2)-th electrode AE2 may be electrically connected to the second reflective electrode layer RL2 through the second contact member CNP2′. The (1-3)-th electrode AE3 may be disposed on the insulating layer INS, and the third contact member CNP3′ may be disposed in the third hole H3, and thus, the (1-3)-th electrode AE3 may be electrically connected to the third reflective electrode layer RL3 through the third contact member CNP3′.

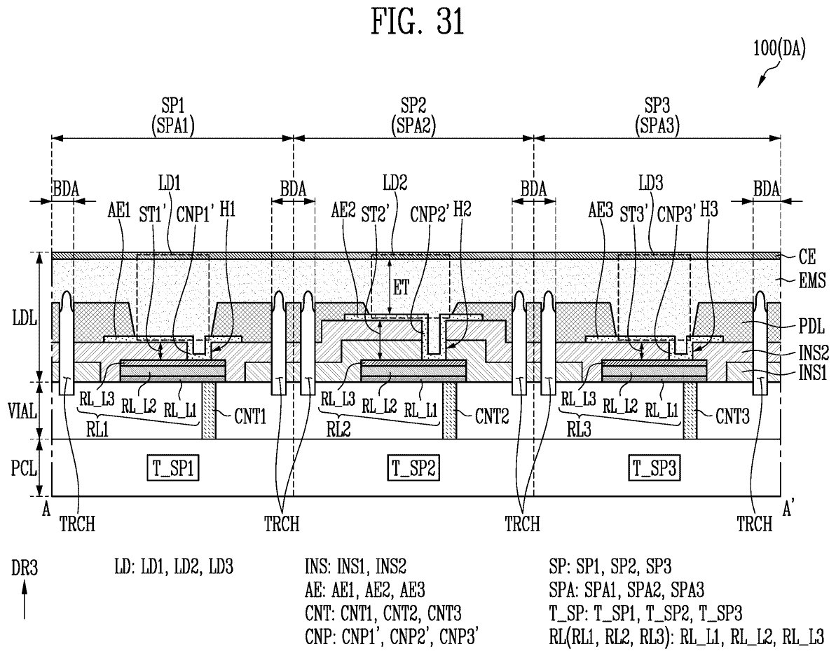

Referring to FIG. 31, the pixel defining layer PDL exposing the (1-1)-th electrode AE1, the (1-2)-th electrode AE2, and the (1-3)-th electrode AE3 may be patterned, and the emission structure EMS and the second electrode CE may be disposed. Accordingly, the first to third light emitting elements LD1 to LD3 may be provided.

Thereafter, according to an embodiment, the encapsulation layer TFE may be disposed, additional layers may be disposed on the encapsulation layer TFE, and the display device 100 may be provided.

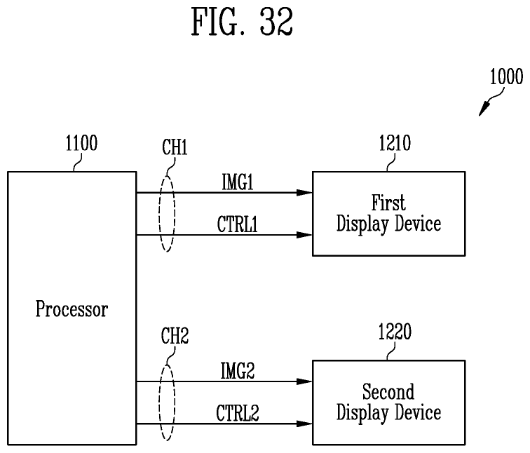

FIG. 32 is a block diagram illustrating an electronic device according to an embodiment.

Referring to FIG. 32, the electronic device 1000 may include a processor 1100, and one or more display devices 1210 and 1220. The electronic device 1000 may implement a display system.

The processor 1100 may perform various suitable tasks and calculations. In some embodiments, the processor 1100 may include an application processor, a graphic processor, a microprocessor, a central processing unit (CPU), and the like. The processor 1100 may be connected to other components of the electronic device 1000 through a bus system and may control the other components.

According to an embodiment, the processor 1100 may provide input image data to the display device 1210, 1220, and the display device 1210, 1220 may display images based on the input image data provided by the processor 1100.

In FIG. 32, the electronic device 1000 includes the first and second display devices 1210 and 1220. The processor 1100 may be connected to the first display device 1210 through a first channel CH1, and may be connected to the second display device 1220 through a second channel CH2.

Through the first channel CH1, the processor 1100 may transmit first image data IMG1 and a first control signal CTRL1 to the first display device 1210. The first display device 1210 may display an image based on the first image data IMG1 and the first control signal CTRL1. The first display device 1210 may be configured similarly to that of the display device 100 described above with reference to FIG. 1.

Through the second channel CH2, the processor 1100 may transmit second image data IMG2 and a second control signal CTRL2 to the second display device 1220. The second display device 1220 may display an image based on the second image data IMG2 and the second control signal CTRL2. The second display device 1220 may be configured similarly to that of the display device 100 described above with reference to FIG. 1.

The electronic device 1000 may include a computing system for providing an image display function, such as a portable computer, a mobile phone, a smart phone, a tablet personal computer (PC), a smart watch, a watch phone, a portable multimedia player (PMP), a navigation device, and an ultra mobile personal computer (UMPC). In addition, the electronic device 1000 may include at least one of a head mounted display (HMD) device, a virtual reality (VR) device, a mixed reality (MR) device, or an augmented reality (AR) device.

According to an embodiment, the electronic device 1000 may further include a memory device, a storage device, an input/output (I/O) device, a power supply.

The memory device may store data needed to perform the operation of the electronic device 1000. The memory device may function as a working memory and/or a buffer memory for the processor 1100. For example, the memory device may include one or more volatile memory devices such as a dynamic random access memory (DRAM) device, a static random access memory (SRAM) device, and a mobile DRAM device.

The storage device may store data in response to control signals or data from the processor 1100. The storage device may include one or more non-volatile storages to retain the data even when the electronic device 1000 is powered off. In some embodiments, the storage device may include a solid state drive (SSD), a hard disk drive (HDD), a CD-ROM, or the like.

The I/O device may include input devices such as a keyboard, a keypad, a touchpad, a touch screen, and a mouse, and output devices such as a speaker and a printer. In an embodiment, the display device 1210, 1220 may be included in the I/O device.

The power supply may supply power needed to perform the operation of the electronic device 1000. For example, the power supply may be a power management integrated circuit (PMIC). In an embodiment, the power supply may supply power to the display device 1210, 1220.

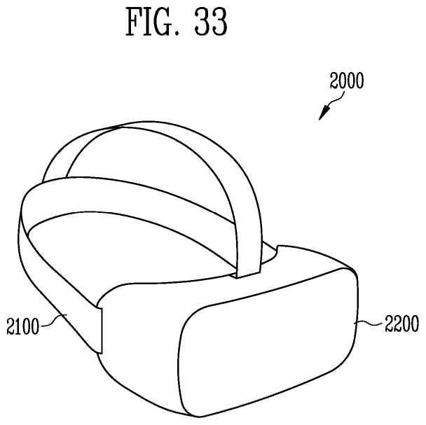

FIG. 33 is a perspective view illustrating an application example of the electronic device of FIG. 32.

Referring to FIG. 33, the electronic device 1000 of FIG. 32 may be applied to a head mounted display device 2000. The head mounted display device 2000 may be a wearable electronic device that may be worn on a user's head.

The head mounted display device 2000 may include a head mount band 2100 and a display device receiving case 2200. The head mount band 2100 may be connected to the display device receiving case 2200. The head mount band 2100 may include a horizontal band and/or a vertical band for fixing the head mounted display device 2000 to the user's head. The horizontal band may be configured to surround (e.g., around a periphery of) a side portion of the user's head, and the vertical band may be configured to surround (e.g., around a periphery of) an upper portion of the user's head. However, the present disclosure is not limited thereto. For example, the head mount band 2100 may be implemented in a glasses frame form, a helmet form, or the like.

The display device receiving case 2200 may receive the first and second display devices 1210 and 1220 described above with reference to FIG. 32. The display device receiving case 2200 may further receive the processor 1100 described above with reference to FIG. 32.

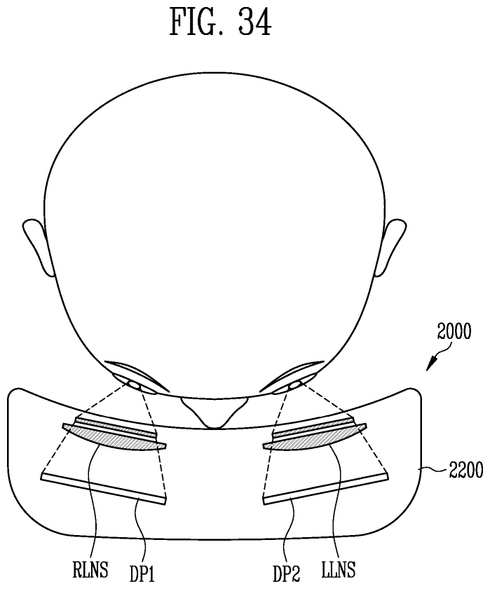

FIG. 34 is a diagram illustrating the head mounted display device of FIG. 33 that is worn by a user.

Referring to FIG. 34, a first display panel DP1 of the first display device 1210 and a second display panel DP2 of the second display device 1220 are disposed in the head mounted display device 2000. The head mounted display device 2000 may further include one or more lenses LLNS and RLNS.

Within the display device receiving case 2200, the right eye lens RLNS may be disposed between the first display device 1210 (which may include the first display panel DP1) and a user's right eye. Within the display device receiving case 2200, the left eye lens LLNS may be disposed between the second display device 1220 (which may include the second display panel DP2) and a user's left eye.

An image output from the first display device 1210 may be displayed to the user's right eye through the right eye lens RLNS. The right eye lens RLNS may refract light from the first display device 1210 to be directed toward the user's right eye. The right eye lens RLNS may perform an optical function for adjusting a viewing distance between the first display device 1210 and the user's right eye.

An image output from the second display device 1220 may be displayed to the user's left eye through the left eye lens LLNS. The left eye lens LLNS may refract light from the second display device 1220 to be directed toward the user's left eye. The left eye lens LLNS may perform an optical function for adjusting a viewing distance between the second display device 1220 and the user's left eye.

In some embodiments, each of the right eye lens RLNS and the left eye lens LLNS may include an optical lens having a pancake-shaped cross-section. In some embodiments, each of the right eye lens RLNS and the left eye lens LLNS may include a multi-channel lens including sub-areas having different optical characteristics. In this case, each display panel DP1 and DP2 may output images respectively corresponding to the sub-areas of the multi-channel lens, and the output images may pass through the respective corresponding sub-areas and may be viewed to the user.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a reflective electrode layer on a substrate, and comprising an uppermost conductive layer;
an insulating layer on the substrate, and at least partially covering a portion of the reflective electrode layer;
a first electrode electrically connected to the reflective electrode layer;
an emission structure electrically connected to the first electrode; and
a second electrode electrically connected to the emission structure,
wherein the reflective electrode layer comprises a first reflective electrode layer in a first sub-pixel area, and a second reflective electrode layer in a second sub-pixel area,
wherein the first electrode comprises a (1-1)-th electrode in the first sub-pixel area and electrically connected to the first reflective electrode layer, and a (1-2)-th electrode in the second sub-pixel area and electrically connected to the second reflective electrode layer,
wherein at least a portion of the insulating layer is located between the (1-2)-th electrode and the second reflective electrode layer, and
wherein the uppermost conductive layer of the first reflective electrode layer has a first thickness, the uppermost conductive layer of the second reflective electrode layer has a second thickness, and the first thickness and the second thickness are equal to each other.

2. The display device according to claim 1, wherein the insulating layer has a first hole exposing the first reflective electrode layer, and a second hole exposing the second reflective electrode layer,
wherein the (1-1)-th electrode is located in the first hole in the first sub-pixel area,
wherein the second hole is a via hole penetrating the insulating layer in the second sub-pixel area,
wherein the (1-1)-th electrode and the (1-2)-th electrode have a flat upper surface, and
wherein the (1-2)-th electrode is electrically connected to the second reflective electrode layer through a contact member located in the second hole.

3. The display device according to claim 1,
wherein the reflective electrode layer further comprises a third reflective electrode layer in a third sub-pixel area,
wherein the first electrode further comprises a (1-3)-th electrode electrically connected to the third reflective electrode layer,
wherein the insulating layer forms a step between the second reflective electrode layer and the (1-2)-th electrode in the second sub-pixel area, does not form a step between the first reflective electrode layer and the (1-1)-th electrode in the first sub-pixel area, and does not form a step between the third reflective electrode layer and the (1-3)-th electrode in the third sub-pixel area, and
wherein the insulating layer has a first step thickness between the second reflective electrode layer and the (1-2)-th electrode, and the first step thickness is 80 nm to 140 nm.

4. The display device according to claim 3, wherein the reflective electrode layer comprises a lower reflective electrode layer, an intermediate reflective electrode layer on the lower reflective electrode layer, and an upper reflective electrode layer on the intermediate reflective electrode layer,
wherein the uppermost conductive layer is the upper reflective electrode layer, and
wherein the lower reflective electrode layer has a thickness of 8 nm to 12 nm and comprises titanium (Ti), the intermediate reflective electrode layer has a thickness of 75 nm to 85 nm and comprises aluminum (Al), and the upper reflective electrode layer has a thickness of 2 nm to 4 nm and comprises titanium nitride (TIN).

5. The display device according to claim 3, wherein the reflective electrode layer comprises a lower reflective electrode layer, an intermediate reflective electrode layer on the lower reflective electrode layer, and an upper reflective electrode layer on the intermediate reflective electrode layer,
wherein the uppermost conductive layer is the upper reflective electrode layer, and
wherein the lower reflective electrode layer has a thickness of 2 nm to 15 nm and has a Ti/TiN/Ti structure, the intermediate reflective electrode layer has a thickness of 75 nm to 85 nm and comprises aluminum (Al), and the upper reflective electrode layer has a thickness of 2 nm to 30 nm and has a TiN/ITO structure or a TiN structure.

6. The display device according to claim 1, wherein the insulating layer comprises a first insulating layer, and a second insulating layer on the first insulating layer,
wherein the first and second insulating layers comprise an inorganic material,
wherein the first insulating layer comprises silicon oxide (SiOx) when the uppermost conductive layer comprises ITO, and
wherein the first insulating layer comprises silicon nitride (SiNx) when the uppermost conductive layer comprises TiN.

7. The display device according to claim 1, further comprising:
a pixel defining layer on the insulating layer between the first and second sub-pixel areas, and exposing at least a portion of the first electrode; and
a trench penetrating the pixel defining layer and the insulating layer,
wherein the trench has a depth of 200 nm to 700 nm and a width of 100 nm to 200 nm, or has a depth of 200 nm to 1200 nm and a width of 50 nm to 300 nm.

8. The display device according to claim 1, further comprising:
a pixel defining layer on the insulating layer between the first and second sub-pixel areas, and exposing at least a portion of the first electrode; and
a protruding separator on the pixel defining layer, and comprising a first protruding separator, and a second protruding separator on the first protruding separator,
wherein the second protruding separator forms a tip structure relative to the first protruding separator.

9. The display device according to claim 1,
wherein the reflective electrode layer further comprises a third reflective electrode layer in a third sub-pixel area,
wherein the first electrode further comprises a (1-3)-th electrode electrically connected to the third reflective electrode layer,
wherein the insulating layer forms a step between the second reflective electrode layer and the (1-2)-th electrode in the second sub-pixel area, does not form a step between the first reflective electrode layer and the (1-1)-th electrode in the first sub-pixel area, and forms a step between the third reflective electrode layer and the (1-3)-th electrode in the third sub-pixel area,
wherein the insulating layer has a first step thickness between the second reflective electrode layer and the (1-2)-th electrode, and has a second step thickness between the third reflective electrode layer and the (1-3)-th electrode, and
wherein the first step thickness and the second step thickness are equal to each other, and are 35 nm to 55 nm.

10. The display device according to claim 1, wherein the reflective electrode layer further comprises a third reflective electrode layer in a third sub-pixel area,
wherein the first electrode further comprises a (1-3)-th electrode electrically connected to the third reflective electrode layer,
wherein the insulating layer forms a step between the second reflective electrode layer and the (1-2)-th electrode in the second sub-pixel area, does not form a step between the first reflective electrode layer and the (1-1)-th electrode in the first sub-pixel area, and does not form a step between the third reflective electrode layer and the (1-3)-th electrode in the third sub-pixel area,
wherein the insulating layer comprises a first insulating layer, and a second insulating layer on the first insulating layer, and
wherein the first insulating layer does not cover the first reflective electrode layer and the third reflective electrode layer, and the second insulating layer covers an upper surface and a side surface of each of the first reflective electrode layer and the third reflective electrode layer.

11. The display device according to claim 1,
wherein the reflective electrode layer further comprises a third reflective electrode layer in a third sub-pixel area,
wherein the first electrode further comprises a (1-3)-th electrode electrically connected to the third reflective electrode layer,
wherein the insulating layer does not form a step between the first reflective electrode layer and the (1-1)-th electrode in the first sub-pixel area, forms a step between the second reflective electrode layer and the (1-2)-th electrode in the second sub-pixel area, and forms a step between the third reflective electrode layer and the (1-3)-th electrode in the third sub-pixel area,
wherein the insulating layer comprises a first insulating layer, and a second insulating layer on the first insulating layer, and
wherein the first insulating layer does not cover the first reflective electrode layer, and the second insulating layer covers an upper surface and a side surface of the first reflective electrode layer.

12. The display device according to claim 1, wherein the reflective electrode layer further comprises a third reflective electrode layer in a third sub-pixel area,
wherein the first electrode further comprises a (1-3)-th electrode electrically connected to the third reflective electrode layer, and
wherein the insulating layer forms a step between the first reflective electrode layer and the (1-1)-th electrode in the first sub-pixel area, forms a step between the second reflective electrode layer and the (1-2)-th electrode in the second sub-pixel area, and forms a step between the third reflective electrode layer and the (1-3)-th electrode in the third sub-pixel area.

13. The display device according to claim 12, wherein the insulating layer has a first step thickness between the first reflective electrode layer and the (1-1)-th electrode, a second step thickness between the second reflective electrode layer and the (1-2)-th electrode, and a third step thickness between the third reflective electrode layer and the (1-3)-th electrode, and
wherein the first step thickness is 125 nm to 165 nm, the second step thickness is 320 nm to 380 nm, and the third step thickness is 125 nm to 165 nm.

14. The display device according to claim 1, further comprising:
a pixel-circuit layer comprising the substrate, a transistor on the substrate, and conductive layers electrically connected to the transistor,
wherein the substrate is a silicon substrate, and
wherein the conductive layers are electrically connected to the reflective electrode layer.

15. A method of manufacturing a display device, the method comprising:
patterning a reflective electrode layer on a substrate;
patterning an insulating layer exposing the reflective electrode layer;
patterning a first electrode electrically connected to the reflective electrode layer;
forming an emission structure electrically connected to the first electrode; and
forming a second electrode electrically connected to the emission structure,
wherein the patterning of the reflective electrode layer comprises patterning a first reflective electrode layer in a first sub-pixel area, and patterning a second reflective electrode layer in a second sub-pixel area,
wherein the patterning of the first electrode comprises patterning a (1-1)-th electrode electrically connected to the first reflective electrode layer, and patterning a (1-2)-th electrode electrically connected to the second reflective electrode layer,
wherein the patterning of the insulating layer comprises forming a first hole exposing the first reflective electrode layer, and forming a second hole exposing the second reflective electrode layer,
wherein the insulating layer does not form a step between the first reflective electrode layer and the (1-1)-th electrode, and forms a step between the second reflective electrode layer and the (1-2)-th electrode, and
wherein the first hole and the second hole are formed in the same process as each other.

16. The method according to claim 15, wherein the patterning of the insulating layer comprises:
forming an area where the (1-1)-th electrode is disposed by exposing the first reflective electrode layer through the first hole; and
forming an area where a contact member electrically connecting the (1-2)-th electrode and the second reflective electrode layer to each other is disposed by exposing the second reflective electrode layer through the second hole.

17. The method according to claim 16, wherein the patterning of the (1-1)-th electrode comprises directly disposing the (1-1)-th electrode on the first reflective electrode layer in the first hole, and
wherein the patterning of the (1-2)-th electrode comprises directly disposing the (1-2)-th electrode on the insulating layer without disposing the (1-2)-th electrode in the second hole.

18. The method according to claim 15, wherein the patterning of the reflective electrode layer further comprises patterning a third reflective electrode layer in a third sub-pixel area,
wherein the patterning of the first electrode further comprises patterning a (1-3)-th electrode electrically connected to the third reflective electrode layer, and
wherein the insulating layer does not form a step between the first reflective electrode layer and the (1-1)-th electrode in the first sub-pixel area, forms a step between the second reflective electrode layer and the (1-2)-th electrode in the second sub-pixel area, and does not form a step between the third reflective electrode layer and the (1-3)-th electrode in the third sub-pixel area.

19. The method according to claim 15, wherein the patterning of the reflective electrode layer further comprises patterning a third reflective electrode layer in a third sub-pixel area,
wherein the patterning of the first electrode further comprises patterning a (1-3)-th electrode electrically connected to the third reflective electrode layer, and
wherein the insulating layer does not form a step between the first reflective electrode layer and the (1-1)-th electrode in the first sub-pixel area, forms a step between the second reflective electrode layer and the (1-2)-th electrode in the second sub-pixel area, and forms a step between the third reflective electrode layer and the (1-3)-th electrode in the third sub-pixel area.

20. An electronic device, comprising:
a processor configured to provide input image data;
a display device configured to display an image based on the input image data; and
a power supply configured to supply power to the display device,
wherein the display device comprises:
a reflective electrode layer on a substrate, and comprising an uppermost conductive layer;
an insulating layer on the substrate, and at least partially covering a portion of the reflective electrode layer;
a first electrode electrically connected to the reflective electrode layer;
an emission structure electrically connected to the first electrode; and
a second electrode electrically connected to the emission structure,
wherein the reflective electrode layer comprises a first reflective electrode layer in a first sub-pixel area, and a second reflective electrode layer in a second sub-pixel area,
wherein the first electrode comprises a (1-1)-th electrode in the first sub-pixel area and electrically connected to the first reflective electrode layer, and a (1-2)-th electrode in the second sub-pixel area and electrically connected to the second reflective electrode layer,
wherein at least a portion of the insulating layer is located between the (1-2)-th electrode and the second reflective electrode layer, and
wherein the uppermost conductive layer of the first reflective electrode layer has a first thickness, the uppermost conductive layer of the second reflective electrode layer has a second thickness, and the first thickness and the second thickness are equal to each other.
